(19) United States
(12) Patent Application Publication
(10) Pub. No.: US 2024/0268042 A1
(43) Pub. Date: Aug. 8, 2024

(54) CONTAINER FOR ELECTRONIC DEVICES

(71) Applicant: Assurant, Inc., New York, NY (US)

(72) Inventors: Tony SAMOR, La Vergne, TN (US); Brandon JOHNSON, Brentwood, TN (US)

(21) Appl. No.: 18/166,337

(22) Filed: Feb. 8, 2023

(51) Int. Cl. H05K 5/02; H05K 5/00; H05K 7/14

(52) U.S. Cl. CPC H05K 5/0217; H05K 5/0018; H05K 5/0247; H05K 5/0256; H05K 7/1498

(57) ABSTRACT

A container may include a container body defining a plurality of recesses configured to hold a plurality of electronic devices, at least one electrical charging device comprising a battery, at least one wiring harness comprising a plurality of devices charging adapters configured to supply power to the plurality of electronic devices from the at least one battery, and at least one computing device comprising at least one processor and at least one non-transitory memory. The non-transitory memory may include computer program instructions that, when executed by the at least one processor, are configured to cause the at least one computing device to determine a location associated with the container and/or one or more of the plurality of electronic devices. Systems and methods associated with such containers may also be provided.

### TECHNICAL FIELD

The present disclosure relates generally to a storage container, and more particularly to a container related to tracking, charging, and/or otherwise processing electronic devices.

### BACKGROUND

Various facilities (e.g., warehouse environments, retail spaces, and other locations) may include many electronic devices (e.g., mobile phones). At scale (e.g., thousands or millions of devices), it is often inefficient and time consuming to electronically monitor and document the location of devices and ensure that each device is properly processed (e.g., charged, checked for integrity, etc.). Many processing steps require slow, sequential processing steps that delay the disposition of the electronic devices. Through applied effort, ingenuity, and innovation, Applicant has solved problems relating to storage and processing of electronic devices by developing solutions embodied in the present disclosure, which are described in detail below.

### BRIEF SUMMARY

In general, the present disclosure provides methods, apparatuses, systems, computing devices, and the like for automatically tracking, charging, and/or otherwise processing electronic devices. In various embodiments, a container may be provided. The container may include a container body defining a plurality of recesses configured to hold a plurality of electronic devices; at least one electrical charging device comprising a battery; and at least one wiring harness comprising a plurality of device charging adapters configured to supply power to the plurality of electronic devices from the at least one electrical charging device.

In some embodiments, the container body further includes a shell and an insert. The insert may be disposed at least partially within the shell and define the plurality of recesses. The insert may include a foam material. In some embodiments, the container may include an external display viewable from a wall defined by the shell. In some embodiments, the at least one wiring harness may include a plurality of ports accessible at a wall of the shell, and the plurality of ports may be electrically connected to the at least one electrical charging device. In some embodiments, the at least one wiring harness includes at least one cable configured to removably electrically connect to one or more of the plurality of electronic devices and/or the at least one electrical charging device. In some embodiments, the container includes a tracker. The tracker may be configured to facilitate identification of a location associated with the container for one or more computing devices.

Various embodiments may include a system. The system may include a container including a container body defining a plurality of recesses configured to hold a plurality of electronic devices; at least one electrical charging device comprising a battery; at least one wiring harness comprising a plurality of devices charging adapters configured to supply power to the plurality of electronic devices from the at least one battery; and at least one computing device comprising at least one processor and at least one non-transitory memory. The non-transitory memory may include computer program instructions that, when executed by the at least one processor, may be configured to cause the at least one computing device to determine a location associated with the container and/or one or more of the plurality of electronic devices.

In some embodiments, the at least one wiring harness may be configured to both electrically charge the plurality of electronic devices and transfer data between the plurality of electronic device and the at least one computing device. In some embodiments, the at least one wiring harness may include at least one cable configured to removably electrically connect to one or more of the plurality of electronic devices and/or the at least one electrical charging device. The at least one cable may include a first cable having a single charge-side connector and a plurality of device-side connectors. The plurality of device-side connectors may each be configured to engage a respective one of the plurality of electronic devices. The single charge-side connector may be configured to electrically connect the respective ones of the plurality of electronic devices to the battery. In some embodiments, the system may include a second cable. The second cable may have a second single charge-side connector and a second plurality of device-side connectors. The second plurality of device-side connectors may define a different form factor than the plurality of device-side connectors of the first cable, such that the second cable is configured to engage one or more different makes or models of electronic devices than the plurality of electronic devices. In some embodiments, the system may include a plurality of electronic devices. The electronic devices may incorporate a tracker to provide locational data for the one or more electronic devices within the container. In some embodiments, the system may include a tracker. The at least one computing device may be configured to determine the location associated with the container and/or the one or more of the plurality of electronic devices via the tracker. The tracker may include one or more visual trackers. In some embodiments, the tracker may include a decodable indicia configured to be imaged by an imaging device associated with the at least one computing device.

Some embodiments of the present disclosure may include a method of utilizing a system for tracking a location of a container and/or one or more of a plurality of electronic devices. The system may include a container and at least one computing device. The container may include a container body defining a plurality of recesses configured to hold a plurality of electronic device; at least one electrical charging device comprising a battery; and at least one wiring harness comprising a plurality of device charging adapters. The method may include supplying power to the plurality of electronic devices from the at least one electrical charging device via the at least one wiring harness; and identifying, via the at least one computing device, a location associated with the container and/or one or more of the plurality of electronic devices.

In some embodiments, identifying, via the at least one computing device, the location associated with the container and/or one or more of the plurality of electronic devices may include detecting a location of a tracker attached to the container and/or one or more of the plurality of electronic devices. In some embodiments, the tracker may include one or more visual trackers attached to the container and/or one or more of the plurality of electronic devices. In some embodiments, the tracker comprises one or more decodable indicia attached to the container and/or one or more of the plurality of electronic devices. Detecting the location of the tracker may include capturing an image of at least a portion of the container and/or one or more of the plurality of electronic devices with a camera, decoding the decodable indicia to identify the container and/or one or more of the plurality of electronic devices, and correlating location data associated with the image with the identity of the container and/or one or more of the plurality of electronic devices to identify the location associated with the container and/or one or more of the plurality of electronic devices.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below.

Other features, aspects, and advantages of the subject matter will become apparent from the description, the drawings, and the claims.

### BRIEF DESCRIPTION OF THE DRAWINGS

The following drawings are illustrations of a particular embodiments of the present disclosure and therefore do not limit the scope of the present disclosure. The drawings are not necessarily drawn to scale and are intended for use in conjunction with the explanation in the following detailed description.

FIG. 1A illustrates a side perspective view of an example container in accordance with various embodiments of the present disclosure.

FIG. 1B illustrates a front perspective view of an example container in accordance with various embodiments of the present disclosure.

FIG. 2 illustrates a partial front perspective view of an example container in accordance with various embodiments of the present disclosure.

FIGS. 3A-3B illustrate example trackers in accordance with various embodiments of the present disclosure.

FIG. 4 illustrates a perspective view of a container having a plurality of electronic devices and an electrical charging device in accordance with various embodiments of the present disclosure.

FIG. 5A-5B illustrate perspective views of containers having a plurality of electronic devices connected directly or indirectly to an electrical charging device via wiring harnesses in accordance with various embodiments of the present disclosure.

FIG. 6 illustrates a side perspective view of an example container having a plurality of electronic devices with a plurality of trackers in accordance with various embodiments of the present disclosure.

FIG. 7 illustrates a schematic diagram of an example controller in accordance with various embodiment of the present disclosure.

FIG. 8 illustrates a schematic diagram of an example computing device in accordance with various embodiments of the present disclosure.

FIG. 9 illustrates a schematic diagram of a system in accordance with various embodiments of the present disclosure.

FIG. 10 illustrates a process for charging and tracking one or more electronic device(s) in accordance with various embodiments of the present disclosure.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative positions of certain components or portions of components. As used herein, the term “or” is used in both the alternative and conjunctive sense, unless otherwise indicated. The term “along,” and similarly utilized terms, means near or on, but not necessarily requiring directly on an edge or other referenced location. The terms “approximately,” “generally,” and “substantially” refer to within manufacturing and/or engineering design tolerances for the corresponding materials and/or elements unless otherwise indicated. The use of such terms is inclusive of and is intended to allow independent claiming of specific values listed. Thus, use of any such aforementioned terms, or similarly interchangeable terms, should not be taken to limit the spirit and scope of embodiments of the present invention. As used in the specification and the appended claims, the singular form of “a,” “an,” and “the” include plural references unless otherwise stated. The terms “includes” and/or “including,” when used in the specification, specify the presence of stated feature, elements, and/or components; it does not preclude the presence or addition of one or more other features, steps, operations, elements, components, and/or groups thereof.

As used herein, the term “battery-powered” is intended to refer to devices capable of receiving electrical power from a battery in at least some circumstances. The term “battery-powered” is intended to be interpreted inclusively and includes devices capable of engaging a battery as well as devices capable of being plugged in to a non-battery power source in at least some circumstances.

Words such as “example,” or “exemplary,” when used herein, are intended to mean “serving as an example, instance, or illustration.” Any implementation described herein as an “example”, “exemplary embodiment”, or the like is not necessarily preferred or advantageous over other implementations.

The components illustrated in the figures represent components that may or may not be present in various embodiments of the invention described herein such that embodiments may include fewer or more components than those shown in the figures while not departing from the scope of the invention.

Aspects of the present disclosure may be implemented as computer program products (e.g., computer program instructions stored on media) that comprise articles of manufacture comprising computer executable instructions. Such computer program products may include one or more software components including, for example, applications, software objects, methods, data structures, and/or the like. A software component may be coded in any of a variety of programming languages with executable instructions configured to be performed by one or more devices. An illustrative programming language may be a higher-level programming language and/or a lower-level programming language such as an assembly language associated with a particular hardware architecture and/or operating system platform/system.

Additionally, or alternatively, aspects of the present disclosure may be implemented as a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, executable instructions, program code, and/or similar terms used herein interchangeably). Such non-transitory computer-readable storage media may include all computer-readable media (including volatile and non-volatile media).

As should be appreciated, various aspects of the present disclosure may also be implemented as methods, apparatuses, systems, computing device(s), and/or the like. As such, aspects of the present disclosure may take the form of a data structure, apparatus, system, computing device(s), and/or the like executing instructions stored on a computer-readable storage medium to perform certain steps or operations. Thus, aspects of the present disclosure may also take the form of an entirely hardware aspect, an entirely computer executable instructions aspect, and/or an aspect that comprises combination of computer executable instructions and hardware performing certain steps or operations.

As used herein, the phrase “in an embodiment,” “in one embodiment,” “according to one embodiment,” and the like generally mean that the particular feature, structure, or characteristic following the phrase may be included in at least one embodiment of the present disclosure and may be included in more than one embodiment of the present disclosure.

The figures of the current embodiments of the disclosure are not necessarily drawn to scale and are provided to illustrate some examples of the invention described. The figures are not to limit the scope of the present embodiment of the invention or the appended claims. Aspects of the example embodiments are described below with reference to example applications for illustration. It should be understood that specific details, relationships, and methods are set forth to provide a full understanding of the example embodiment. One of ordinary skill in the art recognize the example embodiment can be practice without one or more specific details and/or with other methods.

### Overview

The present disclosure relates to a container for holding electronic devices. The container may be trackable (e.g., within a warehouse environment) and/or may be configured to charge the electronic devices while the container remains mobile (e.g., via a battery), which may eliminate a lengthy charging step from a device grading process. Embodiments of the present disclosure provide a container configured to receive a plurality of electronic device within individual recesses, and the recesses may be formed of a foam material. In some embodiments, the electronic devices may be received top-end first to maximize space within the container and allow the charge ports of the electronic devices to face upwardly.

In some embodiments, the electronic devices may be charged by an electrical charging device (e.g., a battery) via a wiring harness. The wiring harness may deliver power to the electronic devices via a wire (e.g., USB connection to the device) or wirelessly (e.g., via an induction charging coil disposed adjacent to the devices). In some embodiments, the wiring harness may include one or more cables and/or one or more connector types at an end of the cable, wherein the one or more cables may be configured to engage with one or more electronic devices (e.g., via USB, Lightning®, ThunderBolt®, or the like). The one or more cables may be configured to transmit power to one or more electronic devices, transfer data to or from one or more electronic devices, and/or facilitate other functionalities (e.g., diagnostic testing, wiping data from one or more electronic devices, etc.).

The cables may connect to one or more additional connectors on the container. These one or more additional connectors may be configured, via an additional cable extending from the container, to connect to at least one computing device. For example, in some embodiments, the container connects to a computing device via an additional cable from the connector to transfer data from one or more electronic devices to a computing device and/or from the computing device to one or more electronic devices. Although described herein as a computing device in some examples, the functions ascribed to the computing device(s) may be performed by one or more devices arranged and/or connected in any configuration and location(s), including remote computing devices, servers, systems, etc.

In some embodiments, the container may be trackable via a tracker attached to or otherwise associated with the container and/or via one or more trackers attached to or otherwise associated with the electronic devices. Some embodiments of the disclosure include trackers on the container, such as decodable indicia (e.g., QR codes), signal transmitters and/or receivers (e.g., GPS, Wi-Fi, NFC, etc.), or other photographically and/or electromagnetically detectable trackers. Various embodiments of the present disclosure may additionally or alternatively include trackers for individual electronic devices.

In an example use case, electronic devices may be transferred to one or more collection facilities for processing, such as in connection with repair, refurbishment, replacement, and/or trade-in workstreams. In such environments, the electronic devices may be processed for later use via one or more steps. For example, an electronic device (e.g., a mobile phone) may be received for processing (e.g., to be refurbished and resold), but must be charged before tests involving the electronic device's electrical systems can be conducted. Typically, the electronic device would need to be plugged in for a substantial period of time before building enough charge to be electronically accessible (e.g., for wiping the device and/or running diagnostics, such as grading the quality of the device). This charging process slows the refurbishment operation and adds time to the overall process. Moreover, keeping track of the location and charge level of each individual device is technically difficult at scale. The containers according to various embodiments of the present disclosure may be configured to hold the electrical devices and charge them while the containers move through various processing functions. In some embodiments, the containers may allow the devices to be removed a short distance for testing (e.g., grading) while the device remains plugged in and charging, such as by a short (e.g., 18 inch) cable connecting the device to the battery, which may avoid any delay in the processing of the device. In some embodiments, the wiring harness(es) may be externally pluggable to be quickly connected, to have their connections traceable, and to allow flexible connections. Internally, the electric charging device may be coupled directly to the electronic devices via the wiring harnesses or indirectly via intermediate electrical connection to ports (e.g., ports 106).

In some embodiments, the electronic devices may be connected to one or more computing devices for data transfer and/or various other connected functionalities (e.g., wiping data, factory resetting, running diagnostics, etc.). In some embodiments, the connection may be made via the wiring harness (e.g., the same USB cables may be used to both deliver power and communicatively couple each electronic device with the computing device) or wirelessly (e.g., via pairing the electronic devices with the computing device using a short range communication technology, such as Wi-Fi, Bluetooth, NFC, or the like).

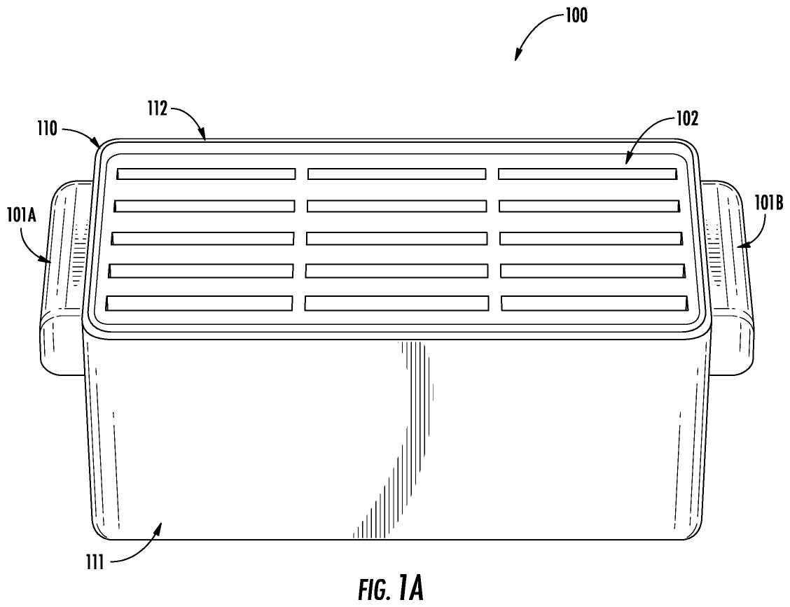

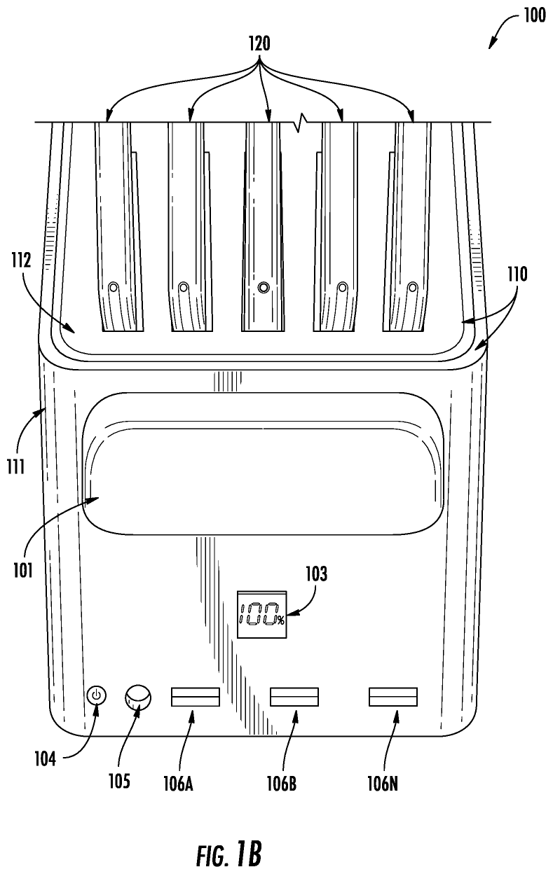

Non-limiting embodiments of the container are described with reference to FIGS. 1A-9. Various components, features, assemblies, and methods are also provided. The embodiments described herein may be used with a plurality of different electronic devices (e.g., mobile phones, such as Samsung® and Apple® devices, tablets, laptop computers, and/or other portable electronic devices).

### Example Containers, Electrical Charging Devices, Tracking, and Wiring

FIGS. 1A-6 depict views of an example container 100 and portions thereof in accordance with various embodiments of the present disclosure. In various embodiments, the container 100 comprises a body 110 having a shell 111 and an insert 112. The shell 111 may have an open top through which the electronic devices may be inserted. For example, in the depicted embodiment, the shell 111 defines a front wall, a back wall, a left wall, a right wall, and/or a bottom surface. In the example depicted in FIG. 1A, the example container further comprises an insert 112 configured to receive and provide cushioning for the electronic devices. The insert may be made of a foam material (e.g., closed or open cell foam, such as polyethylene foam). The foam material may be flexible and able to hold the electronic device(s) without damaging them. In other embodiments, the insert 112 may be made of a rigid material (e.g., plastic, metal, and/or the like). With further reference to FIG. 1A, the insert 112 may have a plurality of recesses 102 configured to receive one or more electronic devices. In the depicted embodiment, the container is configured to receive fifteen (15) electronic devices, and any number of recesses may be used depending on the weight of the container and the number of devices to be processed together. In some embodiments, a container may be retooled for one or more different types of electronic device (e.g., different makes and/or models of mobile phone) by swapping an insert 112 and/or wiring harness.

The container 100 may further include one or more gripping elements 101A, 101B (collectively “101”) (e.g., handles) for a user to grasp. In the depicted embodiments, the gripping elements 101 are disposed on linear opposite sides of the container 100.

With reference to FIG. 1B, the container 100 may include, accessible and/or visible from the exterior of the shell 111 of the container 100, at least one display 103, at least one power switch 104, at least one external connection point 105 (e.g., an A/C adapter and/or data connection point to a computing device), and at least one cable connection point 106, which may be part of the wiring harness discussed herein. In some embodiments, the display 103, power switch 104, external connection 105, and cable connection(s) 106 may be disposed on the same wall of the container 100. While in other various embodiments, the display 103 power switch 104, external connection 105, and cable connection(s) 106 may be disposed on different walls. The container 100 may include a printed circuit board (PCB) having one or more of the display 103, power switch 104, external connection 105, and cable connection(s) 106 disposed thereon, where the PCB may be attached to an inner surface of the shell to align the respective components with openings and/or windows in the shell. For example, the shell 111 may include a window at the location of the display 103. The external connection 105 may comprise an A/C adapter receptacle using any form factor (e.g., 5.50/2.5 mm plug, USB Type A-C, etc.). The cable connection(s) 106 may similarly comprise data and/or charge cable receptacles of any form factor (e.g., USB Type A-C, Thunderbolt®, Lightning®, etc.). The power switch 104 may comprise an actuator switch of any type (e.g., capacitive touch switches, rocker switches, tactile switches, etc.). In some embodiments, the display 103 may comprise any display capable of visually representing information to a user (e.g., LED, LCD, etc.). In some embodiments, the electrical charging device (e.g., electrical charging device 301 shown in FIG. 4) may be connected to the PCB in the interior of the container. For example, a storage space and/or wiring space may be formed between the shell 111 and the insert 112 or within the insert 112 or shell 111.

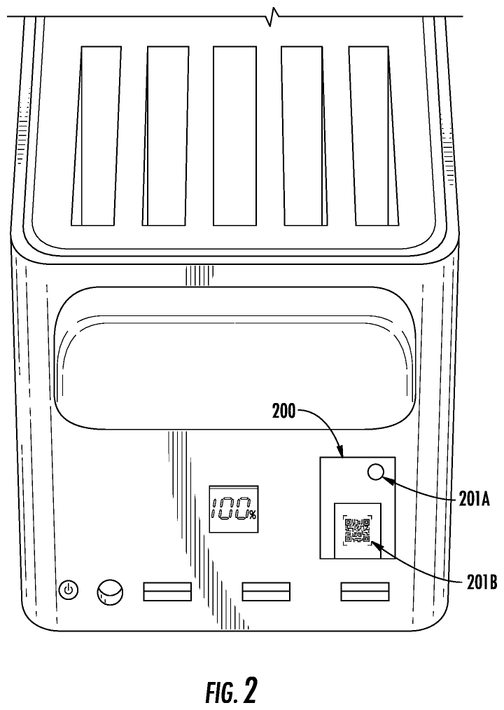

In various embodiments, with reference to FIGS. 1B-2 and 6, the container 100 may further comprise a tracking mechanism 200, wherein the tracking mechanism utilizes one or more trackers 201A, 201B (collectively “201”), and 210. In one or more embodiments, with reference to FIGS. 1B-2, a tracker 201 may provide location data for an individual container 100 to facilitate tracking the container within the processing environment. In some embodiments, the tracker 201 may facilitate differentiating between containers in a multi-container environment. In various embodiments, one or more trackers 201, 210 may be configured to engage with the exterior of the shell 111 of the container 100 to facilitate tracking individual containers and/or devices.

In various embodiments, one or more tracker 210 may be configured to engage with one or more electronic devices 120 to provide tracking for individual electronic devices. With reference to FIG. 6, the tracker 210 may comprise an individual tracker 210 that may provide locational data for an individual row or column within a container and/or an individual electronic device within a container. In the embodiment of FIG. 6, the trackers 210 comprise stickers attached to a bottom of the electronic devices and/or the device-side connectors configured to engage therewith (e.g., such that the stickers are visible from an exterior of the container in an instance in which the electronic devices are disposed in the recesses top first). In some embodiments, the stickers may be added to the devices, for example, during an onboarding process in which the electronic devices are detected and information associated with the electronic devices and/or container are stored for tracking during the various downstream processes described herein. The trackers 210 may be attached to the electronic devices in a manner that facilitates imaging of the trackers from an exterior of the container. In some embodiments, the tracker may be permanently incorporated into the electronic device(s) (e.g., engraved from the factory). In some embodiments, the tracker may be a code displayed on the screen of the device (e.g., a wired or wireless data connection may facilitate the computing device prompting the electronic device(s) to display a decodable indicia.

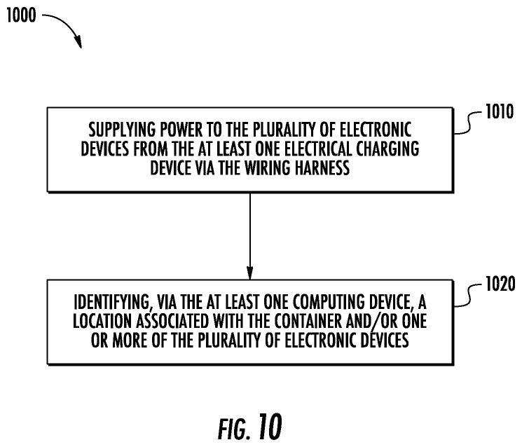

In various embodiments, a tracker may be one or more different technologies, including, but not limited to, RFID tags, QR codes, barcodes, NFC tags, Bluetooth beacons, GPS receivers, Wi-Fi transceivers, and/or the like configured to produce locational data when interacted with at least one computing device. In some embodiments, the trackers 201, 210 may be any type of tracking device configured to be usable for tracking the location of a container and/or electronic device(s). In some embodiments, the trackers 201, 210 may be visual trackers (e.g., decodable indicia such as barcodes, QR codes, labels, etc.) capable of being captured by an imaging device (e.g., imaging device(s) 14 illustrated in FIG. 9). In some embodiments, the trackers 201, 210 may be passive trackers (e.g., barcodes, QR codes, RFID tags, etc.) that are detected by an imaging device or other sensing device (e.g., an RFID reader) without being supplied with power from the container and/or electronic devices. In some embodiments, the trackers 201, 210 may be active trackers (e.g., GPS receivers, Wi-Fi transceivers, accelerometers, etc.) capable of generating signals and/or data for transmitting and/or receiving to/from another computing device. For example, the trackers 201, 210 may include, but are not limited to, RFID tags, NFC tags, Bluetooth beacons, GPS receivers, Wi-Fi transceivers, and/or the like configured to emit a signal, whether passively (e.g., via radio interrogation, such as RFID) or actively (e.g., via active signal generation and transmission, such as Bluetooth), detectable by a computing device for determining the location of the container 100 and/or individual computing devices 120. In some embodiments, the trackers 201, 210 may provide absolute position information themselves (e.g., GPS receivers) or may be used as part of a computing device external to the container for sensing the location of the containers (e.g., a plurality of receivers used to triangulate the position of each container based on a comparison of signal strength measurements received at each of the plurality of receivers). In some embodiments, the trackers 201, 210 may be decodable indicia capable of being captured by an imaging system. The decodable indicia (e.g., QR codes, bar codes, and the like) may comprise computer-decodable indicia identifying the specific container 100 and/or individual electronic devices 120 that are configured to be captured by one or more imaging devices. One or more computing devices may then utilize the image data captured by the imaging device(s) to identify the particular container 100 and/or individual electronic devices 120; identify a location of the container 100 and/or individual electronic devices 120 relative to the imaging device; and identify an absolute location of the container 100 and/or individual electronic devices 120 based on a known position of the imaging device and the relative position of the container 100 and/or individual electronic devices 120 to the imaging device.

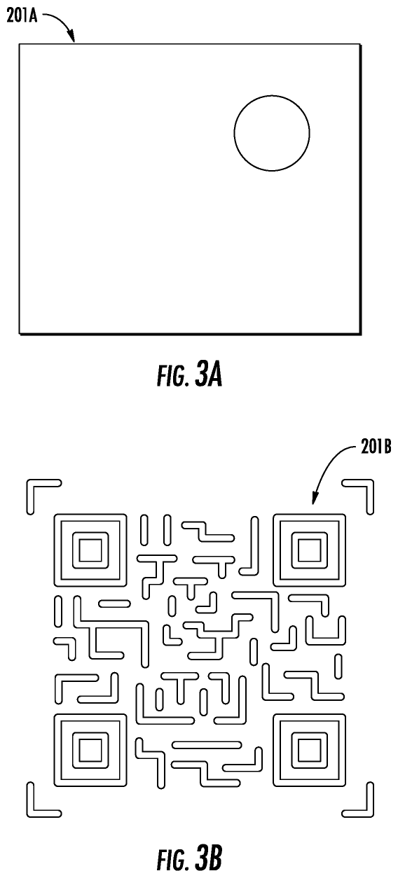

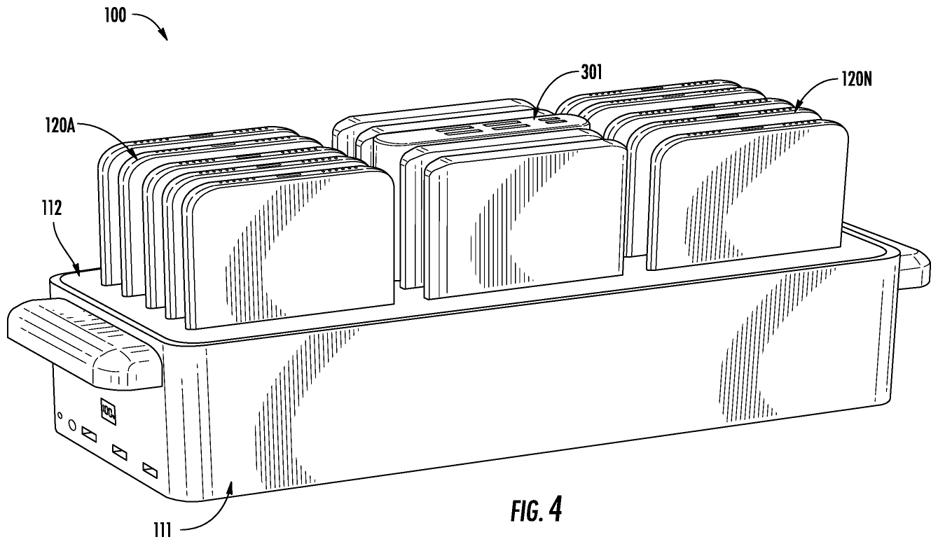

Now referencing FIGS. 3A-3B, in various embodiments, a tracker 201A, 201B (collectively “201”) may be attached to or otherwise visible from an exterior of the shell. For example, decodable indicia (e.g., QR code 201B) may need to be visible to an imaging device to be captured for location determination. Similarly, an electromagnetic passive tracker (e.g., RFID tag 201A) may be attached to or otherwise visible from an exterior of the shell for interrogation by an electromagnetic reader (e.g., an RFID reader). In some embodiments, tracker may be attached to an interior surface of the shell or disposed within an interior cavity of the shell (e.g., non-visual trackers, such as active trackers capable of generating signals and/or data for transmitting and/or receiving to/from another computing device).

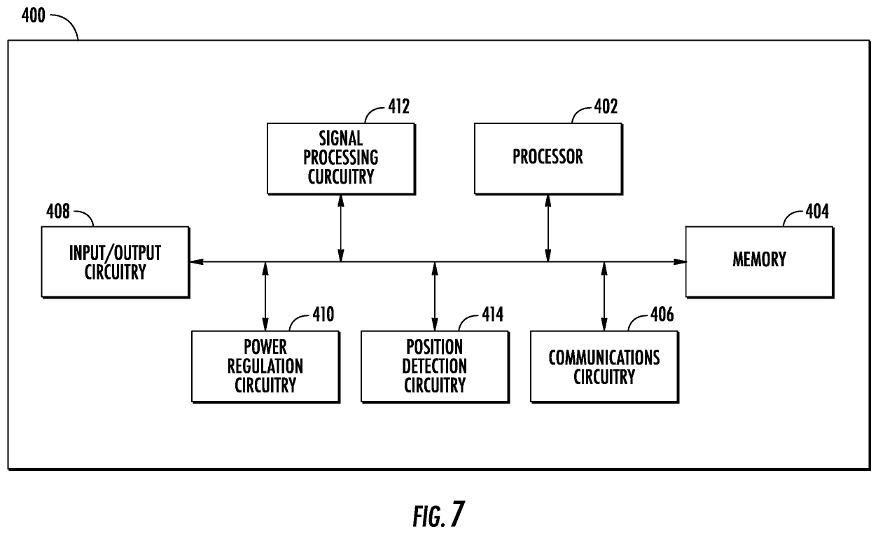

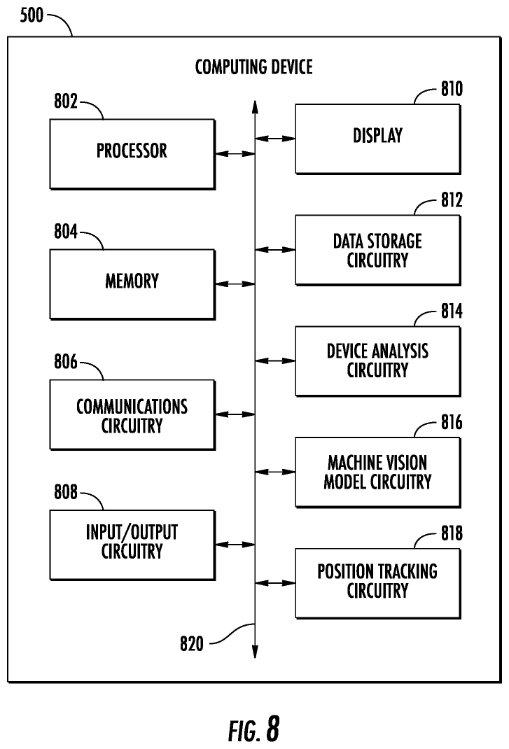

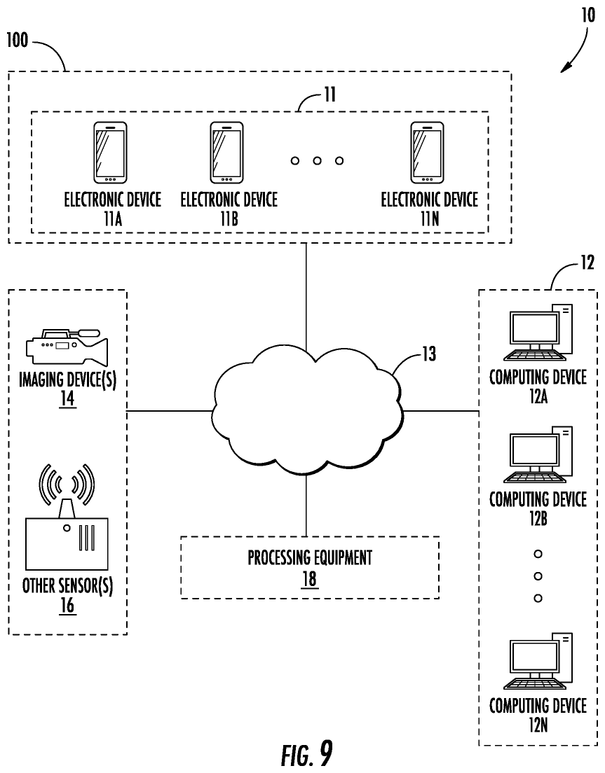

In various embodiments, the tracker 201, 210 can be a plurality of different trackers (e.g., GPS chip, RFID tag, QR code, Wi-Fi, etc.), wherein the trackers 201 can be used in combination and/or substitution with one another. In some embodiments, the tracker In some embodiments, a tracker comprise multiple components capable of collectively facilitating a tracking function. For example, a container 100 may receive absolute position data via a GPS receiver receiving signals from a plurality of GPS satellites (e.g., via communications circuitry 406 and/or position detection circuitry 414 as illustrated in FIG. 7), and the detected position data may be processed and/or transmitted to a computing device via Wi-Fi and/or Bluetooth (e.g., via processor 402, communications circuitry 406, and/or position detection circuitry 414 as illustrated in FIG. 7). For example, a controller of the container (e.g., controller 400 illustrated in FIG. 7) may be configured to receive the GPS signals and calculate an absolute position (e.g., using processor 402), and the controller may then transmit the absolute position (e.g., via communications circuitry 406) to at least one computing device (e.g., computing device 500 shown in FIG. 8) for further processing and/or analysis. In one or more embodiments, a tracker 201 may be configured to passively or actively interact with (or be interacted with by) at least one computing device within a facility, wherein when a tracker 201 interacts with at least one computing device, the computing device receives and/or generates one or more location data with respect to an example container 100.

In one or more embodiments, at least one computing device may comprise or otherwise be operatively coupled to one or more imaging devices (e.g., imaging device(s) 14 illustrated in FIG. 9). In various embodiments, the imaging device(s) may be configured to perform one or more functions associated with the container(s) 100 and/or electronic devices 120. In some examples, the imaging device may be configured to interact with a tracker 201 on a container 100 (e.g., via capturing an image thereof) and transmit image data representative of the image to a processor 802, machine model vision circuitry 816, or the like for analysis thereof. In various embodiments, the one or more imaging device may consist of one or more 2-D imaging devices (e.g., cameras, 2-D imaging sensors, and/or the like), one or more 3-D imaging devices (e.g., time-of-flight image sensor, stereoscopic imaging sensors, and/or the like), and/or the like. In some embodiments, a computer vision model (e.g., a computational neural network or other machine learning model) may be configured to process the image data to determine a location and/or identity of the container and/or electronic devices. For example, in some embodiments, the container and/or electronic devices themselves may be the trackers, with a machine learning model (e.g., via machine vision model circuitry 816) configured to identify and/or determine a location of the container and/or electronic device(s). In various embodiments, the computing device(s) (e.g., computing device 500 shown in FIG. 8) may be configured to track a container, one or more rows and/or columns of electronic devices 120A-120N (columns A-C depicted in FIG. 6), and/or one or more individual electronic devices 120A-120N. In various embodiments, one or more imaging devices, as described above, may be disposed throughout a facility, wherein the one or more imaging devices may be configured to track one or more containers 100 (e.g., via capturing images of trackers).

Various image-based tracking processes may be used without departing from the scope of the present disclosure. For example, an imaging device (e.g., imaging device(s) 14 illustrated in FIG. 9) may be configured to capture a tracker 201, 210 for at least identification purposes. For example, an imaging device may capture an image of a decodable indicia (e.g., a barcode or QR code), a computing device (e.g., computing device 500) may decode the indicia using known algorithms to determine the identity of the container 100 and/or electronic device 120 associated with the indicia (e.g., to decode a serial number associated with the container).

In some embodiments, the imaging device and/or computing device may further be configured to determine the location of the container 100 and/or electronic device(s) using the image data. For example, in some embodiments, the imaging device(s) may have one or more known locations in the facility, such that detecting the identity of the container and the known location of the imaging device that captures the image data associated with the container allows the computing device to determine the location of the container with a sufficient level of granularity (e.g., within a known range/field of view of the imaging device).

In some embodiments, the imaging device(s) may facilitate determination of a more precise location of the container beyond the known location of the imaging device(s). For example, in some embodiments, a plurality of imaging devices may capture images of the container. In such embodiments, the computing device(s) (e.g., via position tracking circuitry 818) may triangulate a position of the container and/or electronic devices via comparison of the multiple sets of image data and the known locations of multiple imaging devices. In some embodiments, the computing device(s) may compare a relative location of a container and/or electronic device(s) with a location of one or more objects or other reference features in a captured image, and the computing device(s) may be configured to calculate a location of the container and/or electronic device(s) based on the known location of the reference feature(s).

In some embodiments, the imaging device(s) and/or computing device(s) may capture and utilize image data for other functions associated with the containers and/or electronic devices. Non-limiting examples of such functions may include device identification (e.g., via machine learning model), external device imaging and grading (e.g., via machine learning model to detect cracks, damage, water, or the like), and text recognition (e.g., reading device displays, serial numbers printed on device cases, text printed on containers, etc.). In some embodiments, the imaging device(s) and/or computing device(s) may capture and utilize image data (e.g., in conjunction with a machine learning model as described herein) to trace the connection points and/or identity of one or more cables of the wiring harness for identifying the individual devices by their respective plugs.

In one or more embodiments, the at least one computing device may be configured to interact with one or more non-visual trackers 201, 210 relating to one or more containers 100 and/or electronic device(s). In various embodiments, the computing device(s) (e.g., computing device 500 shown in FIG. 8) may be configured to track a container, one or more rows and/or columns of electronic devices 120A-120N (columns A-C depicted in FIG. 6), and/or one or more individual electronic devices 120A-120N. In various embodiments, the at least one computing device may further comprise or otherwise operatively connect to one or more other sensor(s) (e.g., other sensors 16 illustrated in FIG. 9). Non-limiting examples of such sensors include, RFID readers, Bluetooth transceivers, Wi-Fi transceivers, GPS receivers, etc., and combinations thereof. rein the sensors may be configured to interact with one or more trackers 201. In various embodiments, the one or more sensors interacts with the one or more trackers 201, 210 associated with the container and/or electronic device(s) (e.g., position detection circuitry 414 shown in FIG. 7, including but not limited to RFID readers, Bluetooth transceivers, Wi-Fi transceivers, GPS receivers, etc.). In some embodiments, one or more of the container, the electronic devices, and/or the computing devices may include or otherwise be operably coupled to circuitry (e.g., sensors) configured to identify and/or detect a location of the container and/or electronic device(s). For example, in an RFID environment, the containers and/or electronic device(s) may comprise RFID trackers 201A and the computing device 500 may include or be coupled with the other sensor(s) 14 in the form of an RFID reader. The RFID reader may transmit an excitation signal towards the RFID tracker 201A, to determine the identity and/or location of the container and/or electronic device(s) bearing the RFID tracker. Similar to the visual location detection discussed above, in some embodiments, non-visual trackers may triangulate (e.g., via a dead reckoning algorithm) the location of a container and/or track the location of the container via the location of the device (e.g., sensor) detecting the container. In another example embodiment, the position detection circuitry 414 (shown in FIG. 7) of the container may comprise a GPS receiver or other absolute position sensor configured to receive position data from a plurality of transmitting devices. In such embodiments, the position detection circuitry 414 may be configured to calculate an absolute position of the container and/or electronic device(s) and transmit the position to the computing device (e.g., no sensor being required, but not prohibited, for the computing device). In some embodiments, the position detection circuitry 414 may be configured to transmit raw position data (e.g., signal strengths from a plurality of surrounding transmitters) and circuitry (e.g., position tracking circuitry 818) may be configured to calculate a location of the container and/or electronic device(s). Similar position detection may be performed with Bluetooth, Wi-Fi, or any transmissive technology. In some embodiments, certain location technologies, such as GPS, may not provide accurate position data in the interior of a building and/or around other closely-spaced electronic devices, and in such instances, another location detection technique may be used.

In one or more embodiments, one or more trackers 201, 210 may be disposed within the container 100, such as when the tracker is not a visual tracker. For example, in various embodiments, one or more containers 100 may be configured with one or more NFC tag, Bluetooth beacon and/or the like, wherein the one or more trackers may be configured to transmit and/or receive one or more radio waves. In various embodiments, the one or more transmitted radio waves may be configured to be respectively transmitted and/or received by one or more computing devices 500, wherein the computing device 500 may comprise communications circuitry 806 (e.g., antenna, and/or the like) to receive the one or more radio waves. The computing device 500 may be configured to receive the radio waves, process the radio waves, and populate locational data associated with the one or more containers 100 within a facility. The communications circuitry 406 (depicted in FIG. 7) may be configured to wirelessly transmit the populated locational data to one or more computing devices 500.

In some embodiments, the container 100 may include a tracker 201, 210 (e.g., as shown in FIG. 2), such that the computing device may image and determine an identity and/or location of the container. In some embodiments, the computing device(s) may store data associated with the electronic devices stored in each container (e.g., a log may be created as the electronic devices are loaded into the container, such as by a user loading the container, and/or detected via the wiring harness to the container, such as by metadata transferred through the wiring harness), such that knowing the location of the container may confer knowledge of the location of the electronic devices within the container. For example, in some embodiments, the electronic devices may be configured to transmit data to a computing device (e.g., upon a USB connection being made). The data may comprise username data, date data, time data, status data, location data, and/or the like for each individual electronic device.

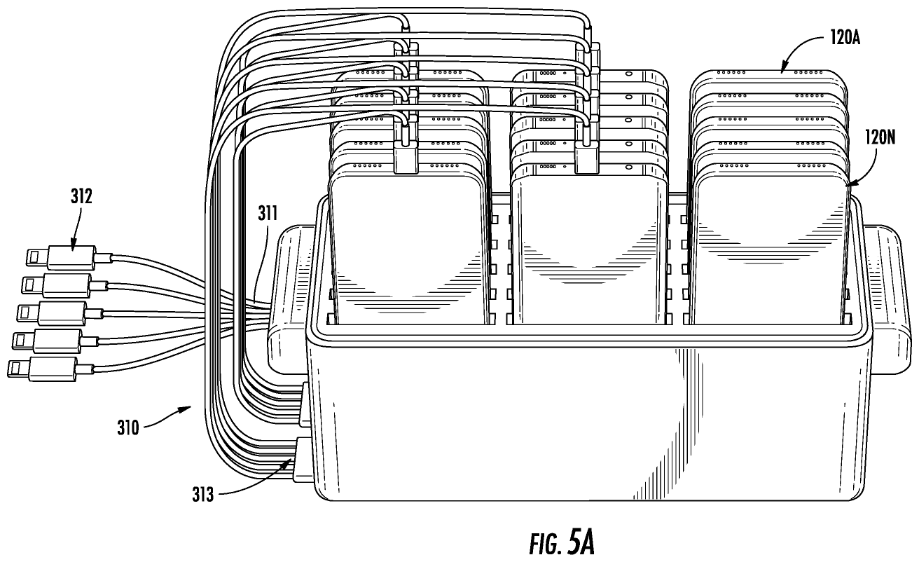

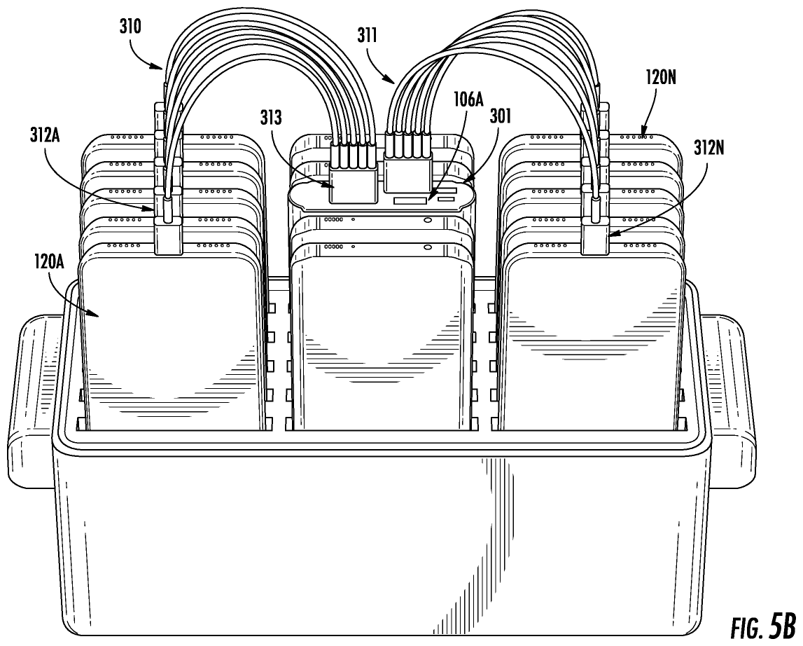

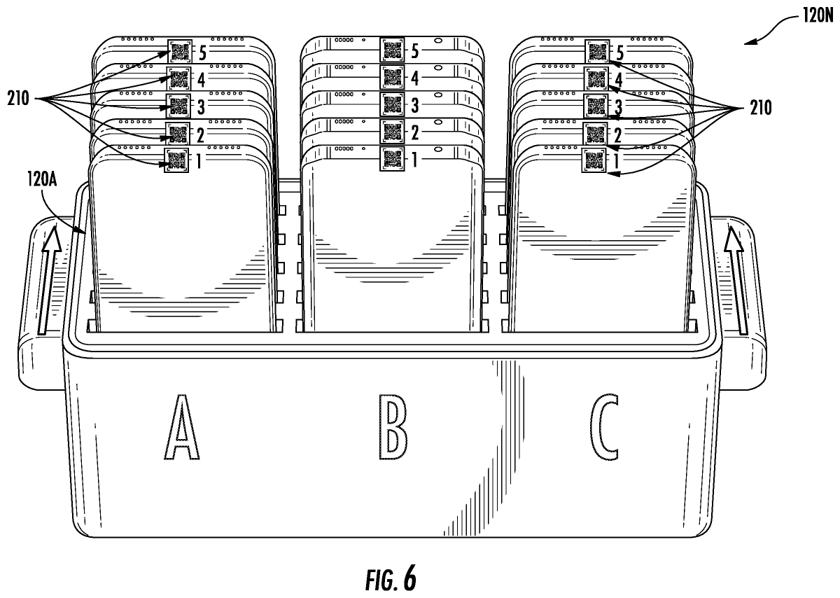

In some embodiments, one or more electronic devices may include separate trackers (e.g., as shown in FIG. 6) such that the imaging device, other sensor(s), and/or computing device, depending on the tracking technology used, may detect the location(s) of the one or more electronic devices independent of the container location. Such separate tracking may be used, for example, in connection with a device grading process, whereby devices are individually analyzed, externally via imaging and/or internally via data connection, and the individual trackers may link camera data and locations with the grading process. In some embodiments, with reference to FIG. 5B, the heights of the recesses in the insert may be staggered such that at least a portion of each electronic device 120 is visible to an imaging device. The depicted and described embodiments described above are example embodiments, and it should be understood that the embodiments are non-limiting to the scope of the application.

In some embodiments, the container 100 and/or individual electronic devices may include a tracker 201, 210 (e.g., as shown in FIGS. 2, 3, and 6), such as a QR Code, GPS, RFID, or other visually detectable and/or otherwise wirelessly or wiredly detectable tracker. For embodiments using a visually detectable tracker (e.g., QR code), a camera may onboard a container and/or individual electronic device by logging into the computing device (e.g., via a web portal, locally-installed application, or the like) and create a profile for the respective container/electronic device. In some embodiments, a camera may image the tracker(s) and associate a particular container the tracker within an internal application. In embodiments in which the container comprises the tracker, an operator may input a number, type, or other data associated with the electronic device(s) to be inserted into the container. In some embodiments, the camera and/or other wired or wireless detection device may capture data associated with the electronic devices. In some embodiments, the camera may image each individual trackers 210 (shown in FIG. 6) of the individual electronic devices adding the electronic devices to the container within the internal application. In some embodiments, both the container and electronic device may be identified (e.g., via detection of a tracker or other identification process, such as manual entry, USB and/or wireless data connection, etc.). In some embodiments, the profile information associated with the container and one or more electronic devices may be stored in the computing device in association with each other (e.g., identifying the electronic devices within a particular container). For example, the computing device(s) may store profiles associated with each electronic device with an association to the container in which they reside, such that each electronic device may be located via its connection to the container. In some embodiments, data associated with one or more electronic devices may be stored in association with one or more other electronic devices, such that their locations are determined to coincide.

In some embodiments, the computing device(s) may include mobile or stationary terminals operating computer software (e.g., computer program instructions) for facilitating the various processes herein. In some embodiments, the computing devices may be local within a facility and/or remote (e.g., a mobile phone, remote monitoring terminal, etc.). In some embodiments, the software may include a portal or other remotely accessed software application. In some embodiments, the software may include a program stored on the computing device(s) (e.g., a mobile application). The computing device(s) and the software described herein may allow real-time or time delayed tracking of the containers and/or electronic devices from a plurality of devices and locations. For example, the software may be configured to render a map comprising the location of one or more containers and/or one or more mobile devices. Such software may be run or otherwise accessed at a mobile device to track the one or more containers and/or one or more mobile devices as a user walks through the facility. In some embodiments, the one or more containers and/or one or more mobile devices may additionally or alternatively be tracked by one or more of the stationary computing devices for tracking and management of the device processes. The various software disclosed herein may facilitate onboarding and setup of profiles associated with the various containers and/or electronic devices described herein, including, in some embodiments, performing scanning and/or data capture processes described above. The various software (e.g., an application running on a mobile device) may be configured to provide an operator with live tracking status of the overall container 100 and/or like tracking status of each individual electronic devices. By way of example, Table 1 below shows an example creation of a profile for a container having a date, time, location, shift, pod, station & username associated with the onboarding of the container.

| | | | Pod, Station, |
|---|---|---|---|
| Date | Time | Location, Shift | Username |
| Nov. 29, 2022 | 1205 | TNla, 3 | 01, 4, Jsmith |

In some embodiments, the software may append these data points into a textual identifier (e.g., a serial no.), such as “1129221205TNla3014/Jsmith” for the embodiment above.

In various embodiments, the container may further comprise one or more wiring harnesses 310 (labeled in FIGS. 5A-5B), wherein the one or more wiring harnesses comprise a plurality of cables 311 with device-side connectors 312 configured to engage with one or more electronic devices and charge-side connectors 313 configure to engage the electrical charging device 301. In some embodiments, the charge-side connectors 313 may carry data signal in addition to charging the devices. The data signal may be configured to request locational data for each individual electronic device engaging with the charge-side connectors 313. In some embodiments, the charge-side connectors 313 may combine multiple cables 311 into a single connector. In some embodiments, the wiring harness may connect directly or indirectly to the respective electrical charging device(s) and/or electronic device(s). For example, one or more intermediate cables, adapters, harnesses, PCBs, connectors, and/or other circuitry and electronic equipment may be disposed between the wiring harness 310 and one or more of the electrical charging device(s) and/or electronic device(s).

In various embodiments, one or more electrical charging devices 301 may be configured to be disposed within a cavity of the shell 111 either permanently or removably, such as within a compartment beneath the insert 112 (e.g., along a bottom of the shell). In some instances, the one or more electrical charging devices 301 may be connected to one or more external-facing ports (e.g., ports 106A-106N shown in FIG. 1B), and the electronic device(s) may then be connected to the one or more electrical charging devices via the ports. As shown in FIG. 5A, in one or more embodiments, one or more electrical charging devices may be disposed within the inner cavity of the shell 111 of a container 100 and connected via ports (e.g., ports 106A-106N shown in FIG. 1B). In various embodiments, the one or more electrical charging devices 301 may connect internally to the plurality of ports (e.g., as depicted in FIG. 1B, 105 and 106A-106N), and the ports may be accessible on one or more walls of the shell 111. In various embodiments, the one or more ports 106A-106N may be configured to engage one or more wiring harnesses 310 (e.g., via at least one charge-side connector 313) and one or more device-side connectors 312 from the wiring harness 310 engage one or more electronic device(s) 120 to deliver power to said device. In some embodiments, external power (e.g., from electrical mains and/or a computing device) may be provided to the container (e.g., directly or indirectly to the electrical charging device or directly or indirectly to one or more electronic devices), such as via a port 106 and/or additional AC-adapter connection.

In various embodiments, the electrical charging device 301 may be configured to provide electrical power to a plurality of electronic devices (e.g., ten or more electronic devices 120), wherein a plurality of wiring harnesses 310 engage with the electrical charging device via a plurality of connection points 106A-106N. For example, the embodiment of FIG. 5A depicts two wiring harnesses 310 each having a single charge-side connector 313 engaging an external port 106A-106N and five device-side connectors 312 engaging individual electronic devices. In the depicted embodiment, each wiring harness 310 may be independently swapped to reconfigure the container for electronic devices having different plug types. For example, the single charge-side connector 313 may be a standard connector configured to engage a port on the container (e.g., USB type A) while the device-side connectors may vary between harnesses such that the harnesses may be interchanged to facilitate different types of connectors on different electronic devices. In the depicted embodiment, changing a single wiring harness reconfigures five slots (via the five device-side connectors) to different connector types. It will be appreciated that any number of ports and connectors may be used per wiring harness. In various embodiments, the one or more electronic charging devices 301 may be actuatable via a power switch 104 (depicted in FIG. 1B) to control the power usage (e.g., the switch may be in an “ON” position before power is delivered). In various embodiments, the one or more electrical charging devices 310 may be configured to engage with a display 103 (depicted in FIG. 1B), such as via a PCB, to display power level information to a user. For example, the display 103 may be configured to show the percentage of electrical charge left in one or more electrical charging devices 301.

With reference to FIGS. 4 and 5B, in some embodiments, the insert 112 may support one or more electrical charging devices that are accessible from a top of the container in addition to or instead of the electrical charging device(s) hidden from view beneath the insert and/or otherwise within the cavity formed by the shell. In the depicted embodiment of FIGS. 4 and 5B, the electrical charging device 301 is disposed vertically within a recess of the insert 112 similar to the electronic devices around it. The electrical charging device 301 may be removable and replaceable (e.g., a portable battery pack, removable battery, etc.), such that one electronic device can be recharged in a charging bay without rendering the container unusable for the duration of charging. Instead, an empty/discharged electrical charging device may be swapped with a full/charged electrical charging device and the container may be immediately returned to service. In some other embodiments, the electrical charging device(s) may be built into the containers, such that the containers may be taken out of service and charged as needed.

As shown in FIG. 5B, in one or more embodiments, one or more electrical charging devices may be disposed within one or more recesses 102 of an insert 112 of a container 100. In various embodiments, an electrical charging device 301 may be configured to fit within one or more designated recesses 102 in an insert 112. In various embodiments, the one or more electrical charging devices 301 may comprise a plurality of ports 106A configured to engage a wiring harness directly. In various embodiments, the electrical charging device 301 may be configured to provide electrical power to a plurality of electronic devices 120 (e.g., ten or more electronic devices 120, such as the depicted fifteen devices). A plurality of wiring harnesses 310 may engage each electrical charging device via a plurality of connection points 106A-106N. In various embodiments, the one or more electronic charging devices 301 may further comprise a power switch (e.g., directly on the electronic charging device(s), on the shell, or elsewhere on the container) to control the power usage.

In one or more embodiments, one example container may be configured to receive electronic devices 120 of only one connector type (e.g., Lightning® connectors). In another example embodiment, another example container 100 may be configured to receive a different connector type (e.g., USB Type-C). In one or more embodiments, a third example container may be configured to receive a different connector type, wherein the connectors may have a plurality of different connection types (e.g., USB Type-C, Micro USB, Lightning®, USB 2.0, Mini USB, etc.) and may be configured to engage with a plurality of electronic devices 120. In some embodiment, the container 100 may have ports (e.g., ports 106A-106N shown in FIG. 1B) having a first connection type, and the electronic devices 120 may have a second connection type which may be the same or different than the first connection type. Multiple wiring harness 310 may be manufactured with a charge-side connector 313 matching the first connection type and with alternative versions of wiring harness each having a different second connection type to be compatible with multiple phone types. For example, in the depicted embodiments, the charge-side connectors are USB Type-A, while the device-side connectors may vary depending on the target electronic device. In such embodiments, a same shell 111 and certain internal components of the container (e.g., including the associated charge circuitry and either including or excluding the insert 112, which may be swappable) may be used for a plurality of different electronic device configurations by exchanging the wiring harness for one compatible with a target device type. In some embodiments, groups of five same device types may be coordinated such that each wiring harness has five electronic devices corresponding to its connector type, while not precluding the other wiring harnesses from having different connector types.

In one or more embodiments, the one or more connectors 312 of the wiring harness 310 may be configured to provide electrical power to one or more electronic devices 120. In one or more embodiments, one or more wiring harnesses 310 may be configured to engage with a plurality of electronic devices 120, wherein the wiring harnesses are configured to extract and/or send data to one or more electronic devices 120. While in other example embodiments, one or more wiring harnesses 310 may be configured to charge and extract and/or send data to a plurality of electronic devices 120.

In one or more example embodiments, the container 100 may be configured for wireless charging. For example, in some embodiments, a plurality of charging coils (e.g., induction coils) may be disposed in an insert 112, such as within one or more walls of one or more recesses to be adjacent the respective electronic device(s). In various embodiments, one or more charging coils may be configured to connect with an electrical charging device 301 of the container. For example, in various embodiments, one or more charging coils may be connected via a cable to the electrical charging device(s). A wiring harness may connect the electrical charging device 301 to the charging coils, and in such embodiments, the wiring harness and/or electrical charging device may be disposed within the cavity of the shell.

In various embodiments, one or more electronic devices may be configured to engage with a wiring harness. In various embodiments, the wiring hardness may be configured to detect the electronic devices with the most amount of power and/or electronic devices with the least amount of power. The wiring harness may further be configured to distribute power evenly across a plurality of electronic devices, wherein the power comes from the one or more electronic devices with the greatest amount of power (e.g., power sharing).

### Example Computing Devices, Controllers, and Systems

As shown in FIG. 7, in one aspect, the container 100 may include a controller 400. In some embodiments, the controller 400 may be configured to perform one or more functions associated with the container, including, but not limited to, power regulation, position detection, communications (e.g., signal transmission and reception), signal processing (e.g., multiplexing multiple cables input to a single port), and/or any other function described herein. In the embodiment depicted in FIG. 7, one or more of the depicted components may be optional, and the controller, if any is used in the container, may be limited to the components and computer program products used to perform the recited functions. The controller 400 may comprise one or more printed circuit boards (PCBs) comprising hardware associated with the controller as described herein (e.g., providing USB connections to an exterior and/or interior of the shell 111). In various embodiments the controller 400 may be part of the electrical charging device, may perform one or more functions associated with the electrical charging device, and/or may be operably coupled with the electrical charging device for performing any of the functions herein. For example, in some embodiments, the electrical charging device may comprise a removable battery pack, and the controller 400 may be within or otherwise associated with the battery pack.

In some embodiments, the controller 400 may include or be in communication with one or more processors (for example, processor 402) (also referred to as processing elements, processing circuitry (whether alone or in combination with memory), and/or similar terms used herein interchangeably) that communicate with other elements within the controller 400 via a bus, for example, or network connection. As will be understood, the processor 402 may be embodied in a number of different ways. For example, the processor 402 may be embodied as one or more complex programmable logic devices (CPLDs), microprocessors, multi-core processors, coprocessing entities, application-specific instruction-set processors (ASIPs), and/or controllers. Further, the processor 402 may be embodied as one or more other processing devices or circuitry. The term circuitry may refer to an entirely hardware aspect or a combination of hardware and computer program products (e.g., software, computer executable instructions, etc.). Thus, the processor 402 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processor 402 may be configured for a particular use (e.g., hard coded with particular functionality) and/or configured to execute instructions stored in volatile or non-volatile media or otherwise accessible to the processor 402. As such, whether configured by hardware or computer program products, or by a combination thereof, the processor 305 may be capable of performing steps or operations according to aspects of the present disclosure when configured accordingly. In some example embodiments, the processor 402 includes one or more processing devices configured to function independently. Additionally or alternatively, in some embodiments, the processor 402 includes one or more processor(s) configured in tandem via the bus to enable independent execution of instructions, pipelining, and/or multithreading. The use of the terms “processor” and “processing circuitry” should be understood to include a single core processor, a multi-core processor, multiple processors internal to the controller 400, and/or one or more remote or “cloud” processor(s) external to the controller 400.

As such, whether configured by hardware or software methods, or by a combination thereof, the processor 402 represents an entity (e.g., physically embodied in circuitry) capable of performing operations according to an embodiment of the present disclosure while configured accordingly. Alternatively or additionally, as another example in some example embodiments, when the processor 402 is embodied as an executor of software instructions, the instructions specifically configure the processor 402 to perform the algorithms embodied in the specific operations described herein when such instructions are executed.

In one aspect, the controller 400 may further include or be in communication with a memory 404. For example, memory 404 may include, but is not limited to, volatile media (also referred to as volatile storage, memory, memory storage, memory circuitry and/or similar terms used herein interchangeably) and/or non-volatile media. In some embodiments, volatile media may include one or more memory elements 404 as described herein, such as random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. As will be recognized, the volatile storage or memory element 404 may be used to store at least portions of the databases, database instances, database management system entities, data, applications, programs, program modules, scripts, source code, object code, byte code, compiled code, interpreted code, machine code, executable instructions, and/or the like being executed by, for example, the processor 402 as shown in FIG. 7. Thus, the databases, database instances, database management system entities, data, applications, programs, program modules, scripts, source code, object code, byte code, compiled code, interpreted code, machine code, executable instructions, and/or the like may be used to control certain aspects of the operation of the controller 400 with the assistance of the processor 402 and operating system. It will be appreciated that where aspects are described to use a computer-readable storage medium, other types of computer-readable storage media may be substituted for or used in addition to the computer-readable storage media described above.

In one aspect, the memory 404 may include non-volatile media (also referred to as non-volatile storage, storage media, memory, memory storage, memory circuitry and/or similar terms used herein interchangeably). In one aspect, the non-volatile storage or memory may include one or more non-volatile storage memory as described above, such as hard disks, solid-state storage, ROM, PROM, EPROM, EEPROM, flash memory, MMCs, SD memory cards, Memory Sticks, CBRAM, PRAM, FeRAM, RRAM, SONOS, racetrack memory, and/or the like. A non-volatile computer-readable storage medium may also include compact disc read only memory (CD-ROM), compact disc-rewritable (CD-RW), digital versatile disc (DVD), Blu-ray disc (BD), any other non-transitory optical medium, and/or the like. As will be recognized, the non-volatile storage may store databases, database instances, database management system entities, data, applications, programs, program modules, scripts, source code, object code, byte code, compiled code, interpreted code, machine code, executable instructions, and/or the like. The term database, database instance, database management system entity, and/or similar terms used herein interchangeably and in a general sense to may refer to a structured or unstructured collection of information/data that is stored in a computer-readable storage medium. The processor 402 and memory 404 may cooperate to perform any of the functionalities associated with the container and controller described herein. It will be appreciated that where aspects are described to use a computer-readable storage medium, other types of computer-readable storage media may be substituted for or used in addition to the computer-readable storage media described above.

The memory 404 may also be embodied as a data storage device or devices, as a separate database server or servers, or as a combination of data storage devices and separate database servers. Further, in some embodiments, the memory 404 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. An example of the aspects contemplated herein would include a cloud data storage system maintained by a third-party provider and where some or all of the information/data required for the operation of the recovery system may be stored. Further, the information/data required for the operation of the recovery system may also be partially stored in the cloud data storage system and partially stored in a locally maintained data storage system. More specifically, memory 404 may encompass one or more data stores configured to store information/data usable in certain aspects.

In various embodiments, the controller 400 may be capable of operating with one or more air interface standards, communication protocols, modulation types, and access types via a communications circuitry 406. For example, the controller 400, via a communications circuitry 406, may be configured to receive and/or provide communication using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the controller 400, via a communications circuitry 406, may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing device 500 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the controller 400 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The controller 400 can also download changes, add-ons, and updates, for instance, to its firmware, software (e.g., including executable instructions, applications, program modules), and operating system.

In some embodiments, the communications circuitry 406 includes hardware, software, firmware, and/or a combination thereof, that supports various functionality associated with generating and/or receiving wired or wireless communications from, to, and/or within the container 100. For example, in some embodiments, the communications circuitry 406 includes hardware, software, firmware, and/or a combination thereof, that receives communications via an antenna and/or wired connection (e.g., Ethernet port). Additionally or alternatively, in some embodiments, the communications circuitry 406 includes hardware, software, firmware, and/or a combination thereof, that routes communications between one or more electronic devices and another one or more electronic devices and/or an external device (e.g., a computing device as discussed herein). In some embodiments, the communications circuitry 406 includes a separate processor, specially configured field programmable gate array (FPGA), or a specially programmed application specific integrated circuit (ASIC). In some embodiments, the communications circuitry 406 is in communication with the processor 402 and/or memory 404 to provide such functionality.

In some embodiments, the controller 400 may include input/output circuitry 408 that provides output to a user and/or one or more electronic devices and, in some embodiments, to receive an indication of a user input and/or communication from one or more electronic devices. In some embodiments, the input/output circuitry 408 is in communication with the processor 402 to provide such functionality. The input/output circuitry 408 may comprise one or more user interface(s) (e.g., display 103 shown in FIG. 1B). In some embodiments, the input/output circuitry 408 also includes one or more touch areas, soft keys, buttons, or other input/output mechanisms. The processor 402 and/or input/output circuitry 408 comprising the processor may be configured to control one or more functions of one or more user interface elements through computer program products comprising computer executable instructions (e.g., software and/or firmware) stored on a memory accessible to the processor (e.g., memory 404, and/or the like). In some embodiments, the input/output circuitry 408 includes or utilizes software application to provide input/output functionality to an external computing device and/or other display associated with a computing device. In some embodiments, the input/output circuitry 408 may function in conjunction with the communications circuitry 406 to facilitate communications to, from, and/or between electronic devices (e.g., external communications may be facilitated by the communications circuitry while intra-container communications may be transmitted via the input/output circuitry, such as via USB connection to the electronic devices). In some embodiments, the input/output circuitry 408 and communications circuitry 406 may comprise the same hardware, software, and/or firmware.

In some embodiments, the controller 400 may include power regulation circuitry 410. The power regulation circuitry 410 may include hardware, software, firmware, and/or a combination thereof, that supports various functionality associated with changing, charging, and/or monitoring a battery level of one or more electronic devices and/or one or more electrical charging devices. For example, in some embodiments, the power regulation circuitry 410 includes hardware, software, firmware, and/or a combination thereof, that identifies a charge level of one or more electronic devices and/or one or more electrical charging devices. Additionally or alternatively, in some embodiments, the power regulation circuitry 410 includes one or more batteries. Additionally or alternatively, in some embodiments, the power regulation circuitry 410 includes hardware, software, firmware, and/or a combination thereof, that directs power to and/or from one or more electronic devices and/or one or more electrical charging devices. For example, in some embodiments, the power regulation circuitry 410 may be configured to detect a charge level of an electronic device, determine that the device needs additional charge, and direct power from an electrical charging device to the electronic device. In some embodiments, the power regulation circuitry 410 may be configured to physically connect the electronic charging device(s) with one or more electronic device(s) with or without additional logic. For example, the electronic charging device(s) may be continually connected to one or more electronic device(s) while the electronic device(s) remain in a charging position (e.g., either plugged in or adjacent a wireless charging coil), and the power supply circuitries of the respective electronic device(s) and/or electrical charging device(s) may control the ultimate delivery of power. In some embodiments, the power regulation circuitry 410 may be configured to stop charging of the electronic devices at a predetermined charge level (e.g., 40%), which may provide sufficient charge for grading and/or any other downstream processes while not overly draining the electrical charging device. In some embodiments, the power regulation circuitry may be configured to stop charging of the electronic devices after a predetermined amount of time has elapsed (e.g., after 15 minutes) with or without detecting the power level of the respective electronic devices' batteries. In some embodiments, the power regulation circuitry 410 may be configured to supply power to maintain a charge level of one or more electronic devices without increasing the total fill level of the electronic device(s) battery. In some embodiments, the power regulation circuitry 410 includes a separate processor, specially configured field programmable gate array (FPGA), or a specially programmed application specific integrated circuit (ASIC). In some embodiments, the power regulation circuitry 410 is in communication with the processor 402 and/or memory 404 to provide such functionality.

In some embodiments, the controller 400 may include signal processing circuitry 412. The signal processing circuitry 412 may include hardware, software, firmware, and/or a combination thereof, that supports various functionality associated with generating, receiving, and/or transmitting data to, from, and within the container 100. For example, in some embodiments, the signal processing circuitry 412 includes hardware, software, firmware, and/or a combination thereof, that receives data from an external computing device for receipt by the container 100, the controller 400, and/or one or more electronic devices. Additionally or alternatively, in some embodiments, the signal processing circuitry 412 includes hardware, software, firmware, and/or a combination thereof, that transmits data from the container 100, the controller 400, and/or one or more electronic devices to an external computing device and/or another of the container 100, the controller 400, and/or one or more electronic devices. In some embodiments, the signal processing circuitry 412 may be configured to multiplex or otherwise combine multiple data transmissions from/to multiple devices for transmission. In some embodiments, the signal processing circuitry 412 includes a separate processor, specially configured field programmable gate array (FPGA), or a specially programmed application specific integrated circuit (ASIC). In some embodiments, the signal processing circuitry 412 is in communication with the processor 402 and/or memory 404 to provide such functionality.

In some embodiments, the controller 400 may include position detection circuitry 414. The position detection circuitry 414 may include hardware, software, firmware, and/or a combination thereof, that supports various functionality associated with identifying a position of the container 100. For example, in some embodiments, the position detection circuitry 414 includes hardware, software, firmware, and/or a combination thereof, that generates position data in an instance in which the position-detection means associated with the container comprises active detection by the container (e.g., a GPS transceiver). Additionally or alternatively, in some embodiments, the position detection circuitry 414 includes hardware, software, firmware, and/or a combination thereof, that generates data indicative of a position (e.g., Wi-Fi signal strength data) for either onboard or off-container processing. In some embodiments, the position detection circuitry 414 may be configured to trigger one or more indicators (e.g., the display of the container, an audible alert, a speaker of electronic device(s), a light or other visual indicator, and/or combinations thereof) to alert a nearby user to the location of the container and/or one or more electronic device(s). In some embodiments, an external computing device (e.g., computing device 500) may transmit a signal to trigger the indicator(s), such as via Bluetooth. In some embodiments, the position detection circuitry 414 includes a separate processor, specially configured field programmable gate array (FPGA), or a specially programmed application specific integrated circuit (ASIC). In some embodiments, the position detection circuitry 414 is in communication with the processor 402 and/or memory 404 to provide such functionality.

In various embodiments, a container 100 may comprise a controller 400, as depicted in FIG. 7, wherein the controller is configured to communicate with one or more computing devices 500. In various embodiments, the controller 400 may be disposed within the shell 111 of a container 100, attached to the shell of the container, or otherwise physically associated with the container (e.g., comprising a PCB configured to support the ports (e.g., input/output circuitry 408) configured to wiredly connect the container, electrical charging device(s), computing device(s) 500, and/or electronic device(s) 120). In one or more example embodiments, a controller 400 may be configured to electronically and/or physically engage with one or more electrical charging devices 301, one or more wiring harnesses 310, and one or more connectors 312, directly or indirectly. In various embodiments, a controller 400 may be configured to interact with one or more portions of the system (e.g., the system illustrated in FIG. 9) and/or one or more trackers 201, 210 in an instance in which such trackers are electronically interactive (e.g., GPS receivers, NFC transmitters, etc.). For example, in various embodiments, a controller 400 may be configured to store a plurality of tracking data from one or more trackers 201, 210, via a memory 404, wherein the controller if further configured to transmit, via communications circuitry 406, the locational data from the memory 404 to a computing device.

In one or more example embodiments, a controller 400 may be configured to communicate with one or more electronic devices 120 within a container 100 via a communications circuitry 406. In various embodiments, a communications circuitry 406 may be configured to engage with one or more electronic devices 120 via one or more wiring harnesses 310 to regulate charge into and/or out of the electronic devices (e.g., via power regulation circuitry 410) and/or to transmit and/or receive data associated with the electronic devices, including executing various functions (e.g., software) on the electronic device(s). In various embodiments, the wiring harnesses 310 may be configured to transmit and/or receive data from one or more electronic devices, wherein the data received from one of more electronic devices may be stored on one or more memories 404 (e.g., whether volatile and/or non-volatile) within the controller and/or may be transmitted externally, such as to a computing device 500. In various embodiments, the communications circuitry 406 may further be configured to interact with one or more computing devices 500. For example, in various embodiments, the communications circuitry 406 may be configured with an additional port (e.g., similar to 106, depicted in FIG. 1B), wherein an additional cable may be configured to extend from the container 100 and connect with a computing device 500. The cable may be configured to transmit and/or extract data from the controller 400 to the computing device 500 and vice versa. In one or more embodiments, the cable, extending from the container to the computing device, may be configured to transmit executable instructions from a computing device, through the communications circuitry 406, through the one or more wiring harnesses 310, to one or more electronic data 120, wherein the executable instructions may be configured to clear the rest of the unwanted data from the electronic devices 120. In various embodiments, the communications circuitry 406 may further configure the container for wireless communication with the electronic device(s) and/or computing device(s).

While FIG. 7 depicts an example controller 400 that may be used with a container according to various embodiments herein, it will be appreciated that in some embodiments, no controller is used in the container(s). Moreover, in some embodiments, only electrical connectors and cables (e.g., part of one or more wiring harnesses) may be used in the container to link the electrical charging device(s) with the electronic device(s) without further processing or computation occurring at the container (e.g., using a passive tracker, such as a visual tracker).

FIG. 8 provides a block diagram of an example computing device 500 according to various embodiments of the present disclosure. In various embodiments, a computing device 500 is configured to allow a user to provide input to the container 100 (e.g., via a user interface of the computing device 500), track one or more containers, and/or receive, display, analyze, and/or otherwise interact with data associated with and/or output from the container 100. While features and functionalities are described with respect to the computing device 500 for example purposes, it will be appreciated that such features and functionalities may be performed by a plurality of devices, including local and/or remote devices. In some embodiments, at least one computing device 500 may be a user device (e.g., a user's personal computer or mobile phone), which may run one or more programs thereon for tracking the container(s) and/or electronic device(s). In some such embodiments, the “user” computing device may communicate with a central or server-level computing device for additional data and/or processing (e.g., operation of a machine learning model). In some embodiments, the tasks described herein may be performed across any number or type of computing devices.

The computing device 500 may include a processor 802, memory 804, communications circuitry 806, input/output circuitry 808, display 810, data storage circuitry 812, device analysis circuitry 814, machine vision model circuitry 816, and/or position tracking circuitry 818 that are in electronic communication with one another via a system bus 220 and/or a network connection or other intra- or inter-device connection. In some embodiments, system bus 220 refers to a computer bus that connects these components so as to enable data transfer and communications between these components. Additionally, or alternatively, the computing device 500 may be in other form(s) and/or may comprise other component(s).

In general, the terms computing device, system, entity, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably. In this regard, the computing device 500 embodies a particular, specially configured computing system transformed to enable the specific operations described herein and provide the specific advantages associated therewith, as described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), network interface(s), storage medium(s), and/or the like, to perform their associated functions, such that duplicate hardware is not required for each set of circuitry. In some embodiments, other elements of the computing device 500 provide or supplement the functionality of another particular set of circuitry. For example, the processor 802 in some embodiments provides processing functionality to any of the sets of circuitry, the memory 804 provides storage functionality to any of the sets of circuitry, the communications circuitry 806 provides network interface functionality to any of the sets of circuitry, and/or the like.

The processor 802 may be embodied in a number of different ways and may, for example, include one or more processing devices configured to perform independently. Additionally, or alternatively, the processor 802 may include one or more processors configured in tandem via a bus to enable independent execution of instructions, pipelining, and/or multithreading. Additionally, in some embodiments, the processor 802 may include one or processors, some which may be referred to as sub-processors, to control one or more components, modules, or circuitry of computing device 500.

The processor 802 may be embodied as one or more complex programmable logic devices (CPLDs), microprocessors, multi-core processors, co-processing entities, application-specific instruction-set processors (ASIPs), and/or controllers. Further, the processor 802 may be embodied as one or more other processing devices or circuitry. The term circuitry may refer to a hardware embodiment or a combination of hardware and computer program products. Thus, the processor 802 may be embodied as integrated circuits, application specific integrated circuits (ASICs), field programmable gate arrays (FPGAs), programmable logic arrays (PLAs), hardware accelerators, another circuitry, and/or the like. As will therefore be understood, the processor 802 may be configured for a particular use or configured to execute instructions stored in volatile or non-volatile media or otherwise accessible to the processor 802. As such, whether configured by hardware or computer program products, or by a combination thereof, the processor 802 may be capable of performing steps or operations according to embodiments of the present disclosure when configured accordingly.

In an example embodiment, the processor 802 may be configured to execute instructions stored in the memory 804 or otherwise accessible to the processor. Alternatively, or additionally, the processor 802 may be configured to execute hard-coded functionality. As such, whether configured by hardware or software methods, or by a combination thereof, the processor may represent an entity (e.g., physically embodied in circuitry) capable of performing operations according to an embodiment of the present disclosure while configured accordingly. Alternatively, as another example, when the processor 802 is embodied as an executor of software instructions, the instructions may specifically configure the processor to perform the algorithms and/or operations described herein when the instructions are executed.

In some embodiments, the memory 804 may be non-transitory and may include, for example, one or more volatile and/or non-volatile memories. In other words, for example, the memory 804 may be an electronic storage device (e.g., a computer readable storage medium). The memory 804 may be configured to store information, data, content, applications, instructions, or the like, for enabling the computing device 500 to carry out various functions in accordance with example embodiments of the present disclosure. In this regard, the memory 804 may be preconfigured to include computer-coded instructions (e.g., computer program code), and/or dynamically be configured to store such computer-coded instructions for execution by the processor 802.

In an example embodiment, the computing device 500 further includes a communications circuitry 806 that may enable the computing device 500 to transmit data and/or information to/from other devices or systems through a network (such as, but not limited to, the imaging device(s) 14 (e.g., cameras) shown in FIG. 9). The communications circuitry 806 may be any means such as a device or circuitry embodied in either hardware or a combination of hardware and software that is configured to receive and/or transmit data from/to a network and/or any other device, circuitry, or module in communication with the computing device 500. In this regard, the communications circuitry 806 may include, for example, a network interface for enabling communications with a wired or wireless communication network. For example, the communications circuitry 806 may include one or more circuitries, network interface cards, antennae, buses, switches, routers, modems, and supporting hardware and/or software, or any other device suitable for enabling communications via a network. Additionally, or alternatively, the communication interface may include the circuitry for interacting with the antenna(s) to cause transmission of signals via the antenna(s) or to handle receipt of signals received via the antenna(s). In some embodiments, either alone or in combination with the controller 400, the communications circuitry 806 may be configured to parse messages to and/or from the electronic devices, including multiplexing and/or interpreting the signals to transmit and receive data to/from multiple electronic devices. In various embodiments, the communications circuitry 806 may be configured for interfacing and/or communicating with the controller 400, for example. For example, the computing device 500 may comprise a communications circuitry 806 for providing executable instructions, command sets, and/or the like for receipt by the controller 400 and/or receiving output and/or the result of a processing the output provided by the computing device 500. In various embodiments, the computing device 500 and the controller 400 may communicate via a direct wired and/or wireless connection and/or via one or more wired and/or wireless networks (e.g., network 13 shown in FIG. 9).

In some embodiments, the computing device 500 includes input/output circuitry 808 that may, in turn, be in communication with the processor 802 to provide output to the user and, in some embodiments, to receive an indication of a user input. The input/output circuitry 808 may comprise an interface or the like configured to be displayed on a display 810. In some embodiments, the input/output circuitry 808 may include a keyboard, a mouse, a joystick, a touch screen, touch areas, soft keys, a microphone, a speaker, or other input/output mechanisms. The processor 802 and/or input/output circuitry 808 may be configured to control one or more functions of one or more user interface elements through computer program instructions (e.g., software and/or firmware) stored on a memory accessible to the processor (e.g., memory 804). The processor 802 and/or input/output circuitry 808 may also be configured to control one or more imaging device(s) 14 alone or in combination with one or more of the device analysis circuitry 814, the machine vision model circuitry 216, and/or the position tracking circuitry 818.

In some embodiments, the computing device 500 includes the display 810 that may, in turn, be in communication with the processor 802 to display user interfaces (such as, but not limited to, display of a call and/or an application). In some embodiments of the present disclosure, the display 810 may include a liquid crystal display (LCD), a light-emitting diode (LED) display, a plasma (PDP) display, a quantum dot (QLED) display, and/or the like.

In some embodiments, the computing device 500 includes the data storage circuitry 812 which comprises hardware, software, firmware, and/or a combination thereof, that supports functionality for generating, storing, and/or maintaining one or more data objects associated with the embodiments of the present disclosure. For example, in some embodiments, the data storage circuitry 812 includes hardware, software, firmware, and/or a combination thereof, that stores data related to image data captured by the imaging device(s) 14. Additionally or alternatively, the data storage circuitry 812 also stores and maintains data related to one or more navigational input command sequences in a data store (e.g., media associated with the data storage circuitry). Additionally or alternatively still, the data storage circuitry 812 also stores and maintains training data for a trained machine vision model associated with the machine vision model circuitry 816 in the data store. In some embodiments, the data storage circuitry 812 can be integrated with, or embodied by, the data store. In some embodiments, the data storage circuitry 812 includes a separate processor, specially configured field programmable gate array (FPGA), or a specially programmed application specific integrated circuit (ASIC).

In some embodiments, the computing device 500 includes device analysis circuitry 814 which comprises hardware, software, firmware, and/or a combination thereof, that supports functionality for analyzing data associated with one or more electronic devices. In one or more embodiments, the device analysis circuitry 814 may work in conjunction with the processor 802 to determine one or more faults with an electronic device. For example, in some embodiments, a data connection may be established (e.g., wirelessly and/or via a wiring harness 310 as shown in FIG. 5A) between one or more electronic devices and the computing device 500. In one or more embodiments, the device analysis circuitry 814 may work in conjunction with the processor 802 to determine metadata associated with an electronic device (e.g., make, model, carrier, IMEI, Serial No., SKU, etc.), which may be input into the trained computer vision model or otherwise used by the computing device 500 as discussed herein. In some embodiments, the metadata may be delivered over wired connection to the computing device(s) from the electronic device(s).

In exemplary embodiments, the computing device 500 includes machine vision model circuitry 816 which comprises hardware, software, firmware, and/or a combination thereof, that supports functionality for creating, training, updating, maintaining, and/or employing a trained machine vision model according to various embodiments of the present disclosure, including for tracking one or more electronic devices. In various embodiments, the machine vision model circuitry 816 can work in conjunction with the processor 802, the input/output circuitry 808, the device analysis circuitry 814, the data storage circuitry 812, the position tracking circuitry 818, and/or the like. In some embodiments, the machine vision model circuitry 816 can control the imaging device(s) 14 of the system and/or receive image data, directly or indirectly, created by the imaging device(s).

In some embodiments, the machine vision model circuitry 816 can direct the imaging device(s) 14 to capture image data related to the location and/or identity of one or more electronic devices. In one or more embodiments, the machine vision model circuitry 816 can use one or more models to identify one or more attributes associated with the electronic devices including, but not limited to, a mobile device manufacturer, a mobile device model, a mobile device operating system, or a combination thereof. Such identity information may be used to identify and/or track individual devices or types of devices within the overall environment and/or within a container. In one or more embodiments, the machine vision model circuitry 816 can use one or more models to determine a location of one or more electronic devices, including determining a location of a container, one or more individual electronic devices, and/or subsets and combinations thereof. For example, in some embodiments the machine vision model circuitry 816 may be configured to direct an imaging device 14 to capture an image of an electronic device represented as image data, and the machine vision model circuitry 816 may then utilize the image data and/or a known location of the imaging device to determine a location of the electronic device.

In some embodiments, the machine vision model circuitry 816 can execute one or more pre-processing steps on the image data (e.g., isolating the electronic device(s) or a portion of the electronic device(s)) to facilitate input into the model. In some embodiments, the machine vision model circuitry 816 may be configured to input one or more images of the electronic device(s) or any portion hereof into the trained machine vision model for analysis.

In exemplary embodiments, the computing device 500 includes position tracking circuitry 818, which comprises hardware, software, firmware, and/or a combination thereof, that supports functionality for tracking the location of container(s) and/or one or more individual electronic devices. In various embodiments, the position tracking circuitry 818 can work in conjunction with the processor 802, the input/output circuitry 808, the device analysis circuitry 814, the data storage circuitry 812, the machine vision model circuitry 816, and/or the like. In some embodiments, the position tracking circuitry 818 may be configured to determine, estimate/predict, and/or store a past, present, or anticipated future location of the container and/or one or more individual electronic devices. In some embodiments, the location can be determined via image analysis and/or any other sensor data (e.g., NFC, RFID, Bluetooth, Wi-Fi, etc.) received in association with a container and/or electronic device(s).

In some embodiments, the location determined by the position tracking circuitry 818 may be provided at any level of granularity or relativity. By way of non-limiting example, the location may be relative to one or more other locations within an environment (e.g., an identification of a station, building, shelf, aisle, room, etc. associated with the electronic device(s)); relative to one or more stages of a process performed on the electronic devices (e.g., a charging mode, a diagnosis mode, a refurbish mode, etc.); and/or an absolute location (e.g., GPS coordinates) without regard to other fixed and/or mobile objects. In some embodiments, the location may be determined as a known location associated with an imaging device 14 (e.g., barcodes scanned by the imaging device may be linked with the location of the imaging device). In some embodiments the location may be determined as an actual location of the electronic device (e.g., by combining a known location associated with an imaging device 14 with image analysis calculating the position of the electronic device relative to the imaging device).

In some embodiments, two or more of the sets of circuitries 802-818 are combinable. Additionally or alternatively, in some embodiments, one or more of the sets of circuitry perform some or all of the functionality described associated with another component. For example, in some embodiments, two or more of the sets of circuitries 802-818 are combined into a single module embodied in hardware, software, firmware, and/or a combination thereof. Similarly, in some embodiments, one or more of the sets of circuitries, for example the communications circuitry 806, the data storage circuitry 812, and/or the device analysis circuitry 814 is/are combined with the processor 802, such that the processor 802 performs one or more of the operations described above with respect to each of these sets of circuitries 806 and 814-818.

As depicted in FIG. 9, the example system 10 comprises one or more computing devices 12. Computing devices 12 (e.g., 12A-12N) may each be interchangeable with computing device 500 shown and described in FIG. 8. In general, the terms computing device, entity, system, and/or similar words used herein interchangeably may refer to, for example, one or more computers, computing devices, computing entities, desktop computers, mobile phones, tablets, phablets, notebooks, laptops, distributed systems, terminals, servers or server networks, blades, gateways, switches, processing devices, set-top boxes, relays, routers, network access points, base stations, the like, and/or any combination of devices adapted to perform the functions, operations, and/or processes described herein. Such functions, operations, and/or processes may include, for example, transmitting, receiving, operating on, processing, displaying, storing, determining, generating/creating, monitoring, evaluating, comparing, and/or similar terms used herein interchangeably. In one embodiment, these functions, operations, and/or processes can be performed on data, content, information, and/or similar terms used herein interchangeably.

In some examples, the computing device(s) 12 may also include one or more network and/or communications interfaces (e.g., communications circuitry 806 shown and described with respect to FIG. 8) for communicating with various computing entities, such as by communicating data, content, information, and/or similar terms used herein interchangeably that can be transmitted, received, operated on, processed, displayed, stored, and/or the like.

As indicated, in some embodiments, the computing device(s) 12 may also include one or more network and/or communications interfaces (e.g., communications circuitry 806 shown and described with respect to FIG. 8) for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing device(s) 12 may be configured to communicate via wireless external communication networks (e.g., communications circuitry 806 shown and described with respect to FIG. 8) using any of a variety of protocols, such as embedded sim (eSIM), remote sim provisioning (RSP), general packet radio service (GPRS), Universal Mobile Telecommunications System (UMTS), Code Division Multiple Access 200 (CDMA200), CDMA200 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), IR protocols, NFC protocols, RFID protocols, IR protocols, ZigBee protocols, Z-Wave protocols, 6LoWPAN protocols, Wibree, Bluetooth protocols, wireless universal serial bus (USB) protocols, and/or any other wireless protocol. The computing device(s) 12 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

As depicted in FIG. 9, any two or more of the illustrative components of the system 10 of FIG. 9 may be configured to communicate with one another via one or more networks 13 (e.g., electronic devices 11A-11N with computing devices 12A-12N). The networks 13 may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks 13 may have any suitable communication range associated therewith and may include, for example, global networks (e.g., the Internet), MANS, WANs, LANs, or PANs. In addition, the networks 13 may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

While FIG. 9 provides an example system 10, it is noted that the scope of the present disclosure is not limited to the example shown in FIG. 9. In some examples, the system 10 may comprise one or more additional and/or alternative elements, and/or may be different from that illustrated in FIG. 9.

In various embodiments, as depicted in FIG. 9, one or more electronic devices 11A-11N (collectively “11”) within one or more containers 100 may be configured to communicate with one or more computing devices 12A-12N (collectively “12”) via a network 13. Electronic device(s) 11 (e.g., 11A-11N) may each be interchangeable with the electronic devices 120A-120N (collectively “120”) shown and described with respect to FIGS. 1B and 4-6. In various embodiments, electronic devices 11 may be configured to connect to the network wirelessly via onboard radios (e.g., Wi-Fi, Hotspot, and/or the like) and/or wiredly (e.g., via direct or indirect USB connection) and communicate to one or more computing devices 12. The computing devices 12 may similarly transmit and/or receive signals via wired and/or wireless connection (e.g., communications circuitry 806 shown and described with respect to FIG. 8). For example, in various embodiments, a plurality of electronic devices 11 may be configured to wiredly and/or wirelessly transmit data to a computing device 12 via the network 13. In various embodiments, one or more computing devices 12 may similarly be configured to wiredly and/or wirelessly transmit data and/or computer executable instructions to one or more electronic devices 11 via the network 13.

In one or more embodiments, the computing devices 12 may be configured to wiredly and/or wirelessly transmit executable instructions via a network 13 to one or more electronic devices 11, wherein the instructions, when executed by the electronic device(s) are configured to cause the electronic device(s) to perform one or more functions, including but not limited to erasing data on the electronic device(s) 11, resetting the electronic device(s) 11, carrying out one or more diagnostics on the electronic devices 11 (e.g., grading), and/or transferring data to or from the electronic devices 11 (including data related to any of the foregoing). In various embodiments, the computing device(s) 12 may be configured to transmit executable instructions after an initial data extraction from one or more electronic devices 11 has been achieved (e.g., data transfer from a memory 404 in the container and/or from memories in the respective electronic devices). In various embodiments, the one or more computing devices may be configured to transmit the data wiping instructions wiredly or wirelessly, via the network 13, directly to one or more electronic devices. In some further embodiments, the one or more computing devices 12, may be configured to transmit the data wiping instructions wiredly or wirelessly to one or more communications circuitries 406 of a controller 400 within one or more containers 100, wherein the one or more communications circuitry 406 may be configured to distribute the executable instructions to the one or more electronic devices 120 wirelessly within the container 100 and/or via one or more wiring harnesses 310. The depicted embodiments described above are example embodiments, and it should be understood that the embodiments are non-limiting to the scope of the application.

In various embodiments, the at least one computing devices may be configured to transmit data wiredly and/or wirelessly, via the network 13. In one or more embodiments, at least one computing device 12 may interact with one or more trackers 201, 210 in one or more manners (e.g., visually, electronically, physically, etc.) in accordance with the various embodiments discussed herein. The interaction may cause a population of one or more location data associated with the container and/or electronic device (e.g., a location within a facility), wherein the location data may be associated with a container, a row of electronic devices, an individual electronic device, and/or various combinations thereof. In various embodiments, the at least one computing device 12 may be configured to transmit the one or more location data to the one or more other computing devices 12 via the network 13. In various embodiments, the computing device 12 may be configured to generate and/or process the one or more location data, store the locational data, provide a user (e.g., via transmission to another computing device, including a handheld or stationary user device) with locations of the objects (e.g., containers, rows of electronic devices, individual devices, and/or the like), and/or the like. In various embodiments, the one or more location data may be processed via a processing device 802 (depicted in FIG. 8) of a computing device 12 to create tracking reports, wherein the tracking reports may be configured to provide a historical location flow path based of at least one computing device engaging with one or more trackers throughout the facility. The depicted embodiments described above are example embodiments, and it should be understood that the embodiments are non-limiting to the scope of the application.

In some embodiments, one or more facility logistics computing devices (e.g., computing device(s) 12) may be configured to direct the operation of processing equipment 18 based on the location data. Non-limiting examples of the processing equipment 18 may include conveyors, forklifts, picking machines, diagnostic devices, cleaning machines, packaging machines, labeling machines, and/or the like. In some embodiments, the one or more facility logistics computing devices (e.g., computing device(s) 12) may be configured to direct the operation of processing equipment 18 to grade, refurbish, and/or package for shipment the one or more electronic devices 11.

In some embodiments, one or more additional devices (e.g., imaging devices 14 and/or other sensors 16) may be included in the system 10, whether integrally with a computing device 12 or as standalone devices communicating with the electronic device(s) 11, computing device(s), and/or processing equipment 18 via one or more networks 13 (e.g., inclusive of direct coupling between the devices, such as a camera connected to a computing device via USB). Some additional non-limiting examples of downstream processes configured to be executed by the system 10 include measuring cycle and lead time for new electronic device(s); tracking dates associated with the receipt of the electronic device(s); and/or searching by QR code or other device or container identifier for its location within the facility.

In various embodiments, one or more wiring harnesses 310 may be configured to engage, via one or more connectors 312 at the end of one or more cables 311, with a plurality of electronic devices 11, 120 within a container 100, wherein the wiring harness 310 may be configured to receive data from one or more electronic devices 11, 120. For example, in one or more embodiments, the wiring harness 310 may be configured to engage with a communications circuitry 406 of a controller 400 at the container 100, with one or more electrical devices 11, 120, and one or more computing devices 12, 500 via one or more cables with or without routing through the controller 400. In one or more embodiments, the controller 400 (e.g., via communications circuitry 460, processor 402, memory 404, and/or signal processing circuitry 412) may be configured to receive executable instructions, process the instructions via a processor 402, and/or distribute the executable instructions to one or more electronic devices. The controller 400 may, in some embodiments, identify one or more target electronic devices 11, 120 of a plurality of electronic devices and direct a portion of a transmission to/from the one or more target electronic devices 11, 120. In some embodiments, the transmissions to/from the computing device(s) 12, 500 may be multiplexed such that a plurality of separate channels may exist between the electronic devices (e.g., one channel per device) and the one or more computing devices 12, 500. The executable instructions may be distributed by cable(s) of one or more wiring harnesses 310 with one or more connectors 312 engaging with electronic devices. The depicted embodiments described above are example embodiments, and it should be understood that the embodiments are non-limiting to the scope of the application.

### Example Methods

FIG. 10 illustrates a flowchart representing a process 1000 for utilizing a system for tracking a location of a container and/or one or more of a plurality of electronic devices. In some embodiments, at least a portion of the process 1000 is embodied by computer program code stored on a non-transitory computer-readable storage medium configured for execution to perform the process as depicted and described. Additionally or alternatively, in some embodiments, the process 1000 is performed by one or more specially configured computing devices such as the computing device 500 alone or in communication with one or more other component(s), device(s), and/or system(s) (e.g., the controller 400). In this regard, in some such embodiments, the computing device 500 is specially configured by computer-coded instructions (e.g., computer program instructions) stored thereon, for example in the memory 804 and/or another component depicted and/or described herein and/or otherwise accessible to the computing device 500, for performing the operations as depicted and described. In some embodiments, the computing device 500 and/or controller 400 are embodied by, or in communication with, one or more external apparatus(es), system(s), device(s), and/or the like, to perform one or more of the operations as depicted and described. For example, the computing device 500 can be in communication with the camera(s) 14, the controller 400, the electronic device(s) 11, and/or the network 13. For purposes of simplifying the description, the process 600 is described as performed by and from the perspective of the computing device 500; however, it will be understood that the recited processes can be performed by one or more of the described devices and such devices may be instantiated in and/or on the container or external to the container for features not requiring a specific location (e.g., visual trackers).

At operation 1010, the computing device 500 includes means, such as the processor 802, memory 804, communications circuitry 806, input/output circuitry 808, display 810, data storage circuitry 812, device analysis circuitry 814, machine vision model circuitry 216, and/or position tracking circuitry 818, or any combination thereof; and/or the controller 400 includes means, such as the processor 402, memory 404, communications circuitry 406, input/output circuitry 408, power regulation circuitry 410, signal processing circuitry 412, and/or position detection circuitry 414, or any combination thereof, that supplies power to the plurality of electronic devices from the at least one electrical charging device via the wiring harness.

At operation 1020, the computing device 500 includes means, such as the processor 802, memory 804, communications circuitry 806, input/output circuitry 808, display 810, data storage circuitry 812, device analysis circuitry 814, machine vision model circuitry 216, and/or position tracking circuitry 818, or any combination thereof; and/or the controller 400 includes means, such as the processor 402, memory 404, communications circuitry 406, input/output circuitry 408, power regulation circuitry 410, signal processing circuitry 412, and/or position detection circuitry 414, or any combination thereof, that identifies a location associated with the container and/or one or more of the plurality of electronic device. In some embodiments, the location detection process may occur constantly or at intervals using one or more trackers (e.g., GPS receivers, Wi-Fi transceivers, and/or the like) transmit signals comprising location data the computing device(s) 500. In some embodiments, the location detection may include imaging a tracker (e.g., a QR code or the like). In some embodiments, both transmissive trackers and visually-detectable trackers may be used. For example, cameras may be positioned at predetermined locations (e.g., at the initial intake/onboarding location within a facility and/or at a final destination within the facility), which cameras may capture image data configured to facilitate detection of the visually-detectable trackers. In addition, or alternatively, a transmissive detector (e.g., GPS or the like) may be used before, during, or after such camera imagery to track the electronic devices. In some embodiments, the visually-detectable trackers may be used to initially associate and/or confirm the association between the tracker and the electronic device or between the tracker/electronic device and the container such that subsequent transmissive trackers may be linked correctly to their corresponding electronic devices. In some embodiments, operations 1010 and 1020 can occur in any order, including simultaneously.

In various embodiments, the electronic device(s) may undergo a sequential processing that includes (1) receiving, (2) charging, (3) grading, and (4) downstream processing. In various embodiments of the present disclosure, at least steps (2) (charging) and (3) (grading) may occur simultaneously or may otherwise overlap.

### CONCLUSION

Although an example system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” and similar terms encompass all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software program, software, software application, script, executable instructions, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results.

1. A container comprising:
a container body defining a plurality of recesses configured to hold a plurality of electronic devices;
at least one electrical charging device comprising a battery; and
at least one wiring harness comprising a plurality of device charging adapters configured to supply power to the plurality of electronic devices from the at least one electrical charging device.

2. The container of claim 1, wherein the container body further comprises a shell and an insert, wherein the insert is disposed at least partially within the shell and defines the plurality of recesses.

3. The container of claim 2, wherein the insert comprises a foam material.

4. The container of claim 1, further comprising an external display viewable from a wall defined by the shell.

5. The container of claim 1, wherein the at least one wiring harness comprises a plurality of ports accessible at a wall of the shell, and wherein the plurality of ports are electrically connected to the at least one electrical charging device.

6. The container of claim 1, wherein the at least one wiring harness comprises at least one cable configured to removably electrically connect to one or more of the plurality of electronic devices and/or the at least one electrical charging device.

7. The container of claim 1, further comprising a tracker, wherein the tracker is configured to facilitate identification of a location associated with the container for one or more computing devices.

8. A system comprising:
a container comprising:
a container body defining a plurality of recesses configured to hold a plurality of electronic devices;
at least one electrical charging device comprising a battery;
at least one wiring harness comprising a plurality of devices charging adapters configured to supply power to the plurality of electronic devices from the at least one battery; and
at least one computing device comprising at least one processor and at least one non-transitory memory, the non-transitory memory comprising computer program instructions that, when executed by the at least one processor, are configured to cause the at least one computing device to:
determine a location associated with the container and/or one or more of the plurality of electronic devices.

9. They system of claim 8, the at least one wiring harness is configured to both electrically charge the plurality of electronic devices and transfer data between the plurality of electronic device and the at least one computing device.

10. The system of claim 8, wherein the at least one wiring harness comprises at least one cable configured to removably electrically connect to one or more of the plurality of electronic devices and/or the at least one electrical charging device.

11. The system of claim 10, wherein the at least one cable comprises a first cable having a single charge-side connector and a plurality of device-side connectors, wherein the plurality of device-side connectors are each configured to engage a respective one of the plurality of electronic devices, wherein the single charge-side connector is configured to electrically connect the respective ones of the plurality of electronic devices to the battery.

12. The system of claim 11, further comprising a second cable comprising a second single charge-side connector and a second plurality of device-side connectors, wherein the second plurality of device-side connectors define a different form factor than the plurality of device-side connectors of the first cable, such that the second cable is configured to engage one or more different makes or models of electronic devices than the plurality of electronic devices.

13. The system of claim 8, comprising a plurality of electronic devices, wherein the electronic devices incorporate a tracker to provide locational data for the one or more electronic devices within the container.

14. The system of claim 8, further comprising a tracker, wherein the at least one computing device is configured to determine the location associated with the container and/or the one or more of the plurality of electronic devices via the tracker.

15. The system of claim 14, wherein the tracker comprises one or more visual trackers.

16. The system of claim 14, wherein the tracker comprises a decodable indicia configured to be imaged by an imaging device associated with the at least one computing device.

17. A method of utilizing a system for tracking a location of a container and/or one or more of a plurality of electronic devices, the system comprising a container and at least one computing device, the container comprising:
a container body defining a plurality of recesses configured to hold a plurality of electronic device;
at least one electrical charging device comprising a battery; and
at least one wiring harness comprising a plurality of device charging adapters;
the method comprising:
supplying power to the plurality of electronic devices from the at least one electrical charging device via the at least one wiring harness; and
identifying, via the at least one computing device, a location associated with the container and/or one or more of the plurality of electronic devices.

18. The method of claim 17, wherein identifying, via the at least one computing device, the location associated with the container and/or one or more of the plurality of electronic devices comprises detecting a location of a tracker attached to the container and/or one or more of the plurality of electronic devices.

19. The method of claim 18, wherein the tracker comprises one or more visual trackers attached to the container and/or one or more of the plurality of electronic devices.

20. The method of claim 18, wherein the tracker comprises one or more decodable indicia attached to the container and/or one or more of the plurality of electronic devices, wherein detecting the location of the tracker comprises:
capturing an image of at least a portion of the container and/or one or more of the plurality of electronic devices with a camera,
decoding the decodable indicia to identify the container and/or one or more of the plurality of electronic devices, and
correlating location data associated with the image with the identity of the container and/or one or more of the plurality of electronic devices to identify the location associated with the container and/or one or more of the plurality of electronic devices.
